(19) United States
(12) Patent Application Publication
(10) Pub. No.: US 2015/0361550 A1
(43) Pub. Date: Dec. 17, 2015

(54) FILM FORMATION APPARATUS, FILM FORMATION METHOD, AND STORAGE MEDIUM

(71) Applicant: TOKYO ELECTRON LIMITED, Tokyo (JP)

(72) Inventors: Kazuo YABE, Nirasaki City (JP); Akira SHIMIZU, Nirasaki City (JP)

(21) Appl. No.: 14/731,468

(22) Filed: Jun. 5, 2015

(30) Foreign Application Priority Data
Jun. 16, 2014 (JP) 2014-123514

(51) Int. Cl. C23C 16/455; H01L 21/02; C23C 16/458

(52) U.S. Cl. CPC C23C 16/45544; C23C 16/45536; C23C 16/45557; C23C 16/45559; C23C 16/4584; C23C 16/45582; H01L 21/02274; H01L 21/0228; H01L 21/02164; H01L 21/02205

(57) ABSTRACT

Film formation apparatus includes: rotation mechanism to repeat alternately placing the substrate in first region and second region; raw material gas supply unit to supply the first region with gaseous raw material; processing space formation member to move up and down to form processing space isolated from the first region; atmosphere gas supply unit to supply atmosphere gas for forming ozone atmosphere where chain decomposition reaction is generated; energy supply unit to forcibly decompose the ozone by supplying energy to the ozone atmosphere and to obtain the oxide by oxidizing the raw material adsorbed to surface of the substrate; buffer region connected to the processing space and being supplied with inert gas; and partition unit to partition the buffer region off from the processing space when the atmosphere gas is supplied to the processing space and to have the buffer region communicate with the processing space when ozone is decomposed.

### CROSS-REFERENCE TO RELATED APPLICATION

This application claims the benefit of Japanese Patent Application No. 2014-123514, filed on Jun. 16, 2014, in the Japan Patent Office, the disclosure of which is incorporated herein in its entirety by reference.

### TECHNICAL FIELD

The present disclosure relates to a film formation apparatus and method for forming an oxide film on a substrate in a vacuum atmosphere, and a non-transitory computer readable storage medium used in the film formation method and apparatus.

### BACKGROUND

In the manufacture process of semiconductor devices, a process for oxidizing a surface of a semiconductor wafer (hereinafter also referred to as a ^{┌}wafer_{┘}), that is, a substrate, may be performed on the semiconductor wafer. A technology for performing the oxidation is disclosed.

For example, atomic layer deposition (ALD) has been known as a process for performing oxidation. Processing for forming a thin film, such as a silicon oxide (SiO₂) film, on a surface of a wafer using ALD may be performed. In a film formation apparatus for performing the ALD, the mounting unit for loading a wafer thereon is installed in a processing chamber (vacuum chamber) the inside of which is under a vacuum atmosphere. Furthermore, the supply of a raw material gas including a silicon raw material and the oxidization of the raw material adsorbed to the wafer are alternately repeated on the loaded wafer several times.

The oxidization of the raw material is performed by supplying an oxidizing gas, such as oxygen or ozone, to the wafer or supplying hydrogen and oxygen to the wafer so that oxygen radicals are generated or plasma is formed with oxygen within the vacuum chamber. However, when the oxidizing gas is supplied, the wafer needs to be heated at a relatively high temperature in order for the oxidizing gas to chemically react with the raw material. Further, when the oxygen radicals are generated, in order to generate the radicals, the wafer needs to be heated at a relatively high temperature. When the oxygen plasma is used, components of the raw material gas accumulated in the wafer may be oxidized even at room temperature. However, film quality becomes different between a planar section and a lateral section of a pattern of the wafer due to straightness of plasma active species formed of ions or electrons, thereby making the film quality of the lateral section poorer than the film quality of the planar section. For this reason, it is difficult to apply such an oxygen plasma when forming a fine pattern.

For this reason, in the related art, a heating unit, such as a heater, is installed in a film formation apparatus. However, when the heating unit is installed as described above, the manufacture cost or operation cost of the film formation apparatus is increased. Further, when the heating unit is installed as described above, it is difficult to reduce a processing time because the raw material is not oxidized until the wafer is heated up to a specific temperature after the wafer is carried into the vacuum chamber. A technology is known in the related art in which the oxidation is performed at room temperature. However, in such a technology, a pressure rises suddenly in a processing space within the processing chamber due to a chain decomposition reaction when oxidation is performed. Specifically, the pressure within the processing space is increased to 20 to 30 times the pressure prior to the chain decomposition reaction. Accordingly, it is difficult to apply such a technology to an actual film formation apparatus. Further, in the related art, it is known that reactive species (atomic oxygen) are generated by supplying an oxygen gas, a nitrogen gas, and a hydrogen gas under reduced-pressure atmosphere and mixing the gases. However, the manufacture cost or operation cost of the film formation apparatus is increased, because temperature of the atmosphere under which each gas is supplied becomes 400 to 1200 degrees C. through heating by the heater in order to generate the atomic oxygen.

Embodiments of the present disclosure provide a technology capable of obtaining an oxide film of good properties and preventing an excessive rise of pressure within a processing space by sufficiently performing an oxidation without using a heating unit for heating a substrate in forming the oxide film in the substrate by repeating a cycle including: adsorption of raw material to the substrate; and oxidization of the raw material.

### SUMMARY

According to an embodiment of the present disclosure, a film formation apparatus configured to obtain a thin film by stacking a molecule layer of oxide on a surface of a substrate loaded onto a table under a vacuum atmosphere formed within a vacuum chamber is provided. The film formation apparatus includes: a rotation unit configured to repeat alternately placing the substrate in a first region and a second region disposed in a circumference direction of the table over the table by rotating the table with respect to the first region and the second region; a raw material gas supply unit configured to supply the first region with a raw material in a gaseous state as a raw material gas so that the raw material is adsorbed to the substrate; a processing space formation member configured to move up and down with respect to the table in order to form a processing space near the substrate placed in the second region, the processing space being isolated from the first region; an atmosphere gas supply unit configured to supply an atmosphere gas for forming an ozone atmosphere including ozone of a concentration that is equal to or higher than a concentration at which a chain decomposition reaction is generated in the processing space; an energy supply unit configured to forcibly decompose the ozone by supplying energy to the ozone atmosphere so that active species of oxygen are generated and to obtain the oxide by oxidizing the raw material adsorbed to a surface of the substrate by the active species; a buffer region configured to be connected to the processing space in order to reduce a rise of pressure in the processing space attributable to the decomposition of the ozone, the buffer region being supplied with an inert gas; and a partition unit configured to partition the buffer region from the processing space when the atmosphere gas is supplied to the processing space and to have the buffer region communicate with the processing space when the decomposition of the ozone is generated.

According to another embodiment of the present disclosure, a film formation method for obtaining a thin film by stacking a molecule layer of oxide on a surface of a substrate loaded onto a table under a vacuum atmosphere formed within a vacuum chamber is provided. The film formation method includes: repeating to alternately place the substrate in a first region and second region disposed in a circumference direction of the table over the table by rotating the table with respect to the first region and the second region; supplying the first region with a raw material in a gaseous state as a raw material gas so that the raw material is adsorbed to the substrate; moving a processing space formation member up and down with respect to the table in order to form a processing space near the substrate placed in the second region, the processing space being isolated from the first region; supplying an atmosphere gas for forming an ozone atmosphere including ozone of a concentration that is equal to or higher than a concentration at which a chain decomposition reaction is generated in the processing space; forcibly decomposing the ozone by supplying energy to the ozone atmosphere so that active species of oxygen are generated, and obtaining the oxide by oxidizing the raw material adsorbed to a surface of the substrate by the active species; supplying an inert gas to a buffer region formed to reduce a rise of pressure in the processing space attributable to the decomposition of the ozone; and partitioning the buffer region from the processing space when the atmosphere gas is supplied to the processing space, and having the buffer region communicate with the processing space when the decomposition of the ozone is generated.

According to another embodiment of the present disclosure, a non-transitory computer-readable storage medium in which a computer program used in a film formation apparatus configured to obtain a thin film by stacking a molecule layer of oxide on a surface of a substrate under a vacuum atmosphere formed within a vacuum chamber has been stored, wherein the computer program includes steps organized so as to execute the film formation method.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a longitudinal-section side view of a film formation apparatus in accordance with a first embodiment of the present disclosure.

FIG. 2 is a cross-section plan view of the film formation apparatus.

FIG. 3 is a perspective view of the inside of a vacuum container installed in the film formation apparatus.

FIG. 4 is a longitudinal-section side view of a cover installed in the film formation apparatus.

FIG. 5 is a lower-side perspective view side of the cover.

FIG. 6 is a process diagram illustrating oxidation processing for a wafer by the cover.

FIG. 7 is a process diagram illustrating oxidation processing for the wafer by the cover.

FIG. 8 is a process diagram illustrating oxidation processing for the wafer by the cover.

FIG. 9 is a process diagram illustrating oxidation processing for the wafer by the cover.

FIG. 10 is a process diagram illustrating oxidation processing for the wafer by the cover.

FIG. 11 is a schematic diagram illustrating a state of the wafer when the film formation is performed.

FIG. 12 is a schematic diagram illustrating a state of the wafer when the film formation is performed.

FIG. 13 is a schematic diagram illustrating a state of the wafer when the film formation is performed.

FIG. 14 is a schematic diagram illustrating a state of the wafer when the film formation is performed.

FIG. 15 is a schematic diagram illustrating a state of the wafer when the film formation is performed.

FIG. 16 is a schematic diagram illustrating a state of the wafer when the film formation is performed.

FIG. 17 is a process diagram illustrating a film formation performed by the film formation apparatus.

FIG. 18 is a process diagram illustrating a film formation performed by the film formation apparatus.

FIG. 19 is a process diagram illustrating a film formation performed by the film formation apparatus.

FIG. 20 is a process diagram illustrating a film formation performed by the film formation apparatus.

FIG. 21 is a process diagram illustrating a film formation performed by the film formation apparatus.

FIG. 22 is a process diagram illustrating a film formation performed by the film formation apparatus.

FIG. 23 is a process diagram illustrating a film formation performed by the film formation apparatus.

FIG. 24 is a process diagram illustrating a film formation performed by the film formation apparatus.

FIG. 25 is a process diagram illustrating a film formation performed by the film formation apparatus.

FIG. 26 is a chart illustrating a process for processing a sheet of a wafer in the film formation.

FIG. 27 is a longitudinal-section side view of a hood installed in a film formation apparatus in accordance with a second embodiment of the present disclosure.

FIG. 28 is a process diagram illustrating a processing performed by the hood.

FIG. 29 is a process diagram illustrating a processing performed by the hood.

FIG. 30 is a longitudinal-section side view of a hood installed in a film formation apparatus in accordance with a third embodiment of the present disclosure.

FIG. 31 is a process diagram illustrating a processing performed by the hood.

FIG. 32 is a process diagram illustrating a processing performed by the hood.

FIG. 33 is a graph illustrating results of an evaluation test.

FIG. 34 is a graph illustrating results of an evaluation test.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### First Embodiment

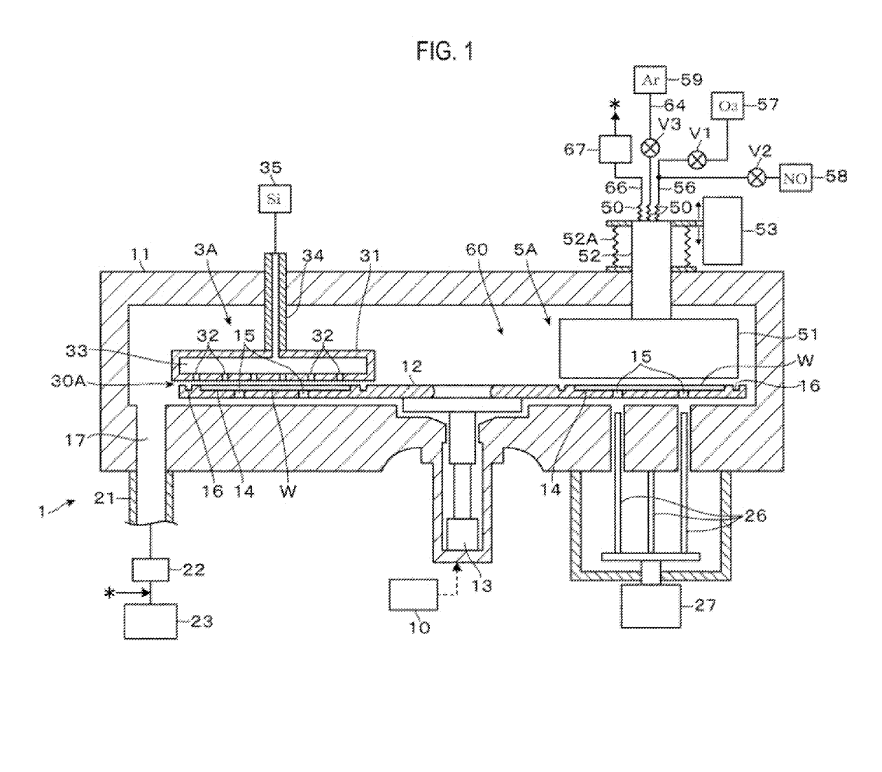

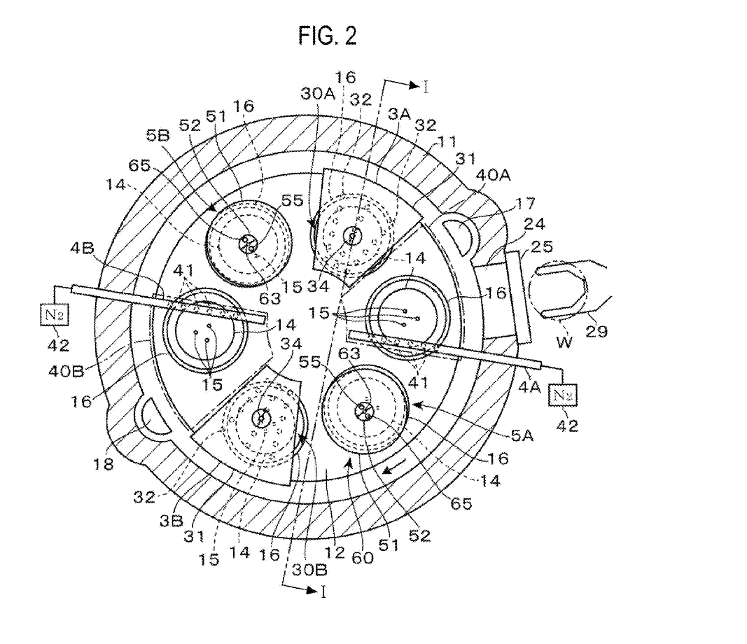

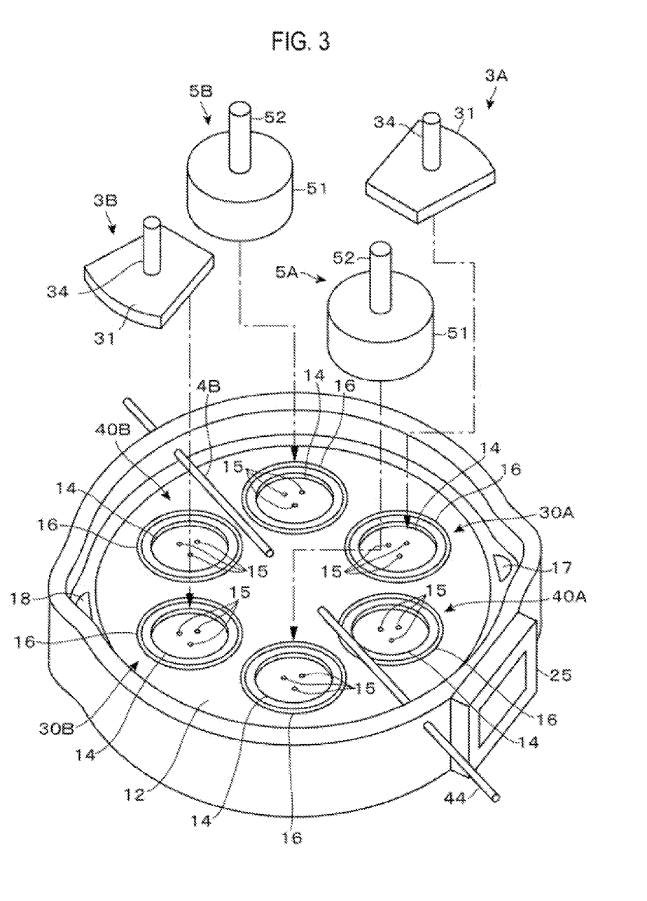

A film formation apparatus 1 in accordance with a first embodiment of the present disclosure is described with reference to FIGS. 1 and 2 illustrating a longitudinal-section side view and a cross-section plan view, respectively, of the film formation apparatus 1. The film formation apparatus 1 forms a silicon oxide film on a wafer W, that is, a substrate, using ALD. The film formation apparatus 1 includes a vacuum chamber 11. An inside of the vacuum chamber 11 is exhausted to become a vacuum atmosphere. The vacuum chamber 11 is formed in a shape of an approximately flat circle. The inside of the vacuum chamber 11 is not subject to heating and cooling from the outside of the vacuum chamber 11, that is, the inside of the vacuum chamber 11 is maintained at room temperature. Each of subsequent reactions is performed at room temperature. FIG. 1 illustrates a cross-section of the film formation apparatus at a location indicated by a two-dot chain line I-I of FIG. 2 when a rotary table 12 to be described later is slightly rotated from the state of FIG. 2. FIG. 3 is a schematic perspective view illustrating the inside of the vacuum chamber 11. Reference is also made to FIG. 3.

The rotary table 12 that is horizontal and circular is provided in the vacuum chamber 11 and rotated in its circumferential direction by a rotation mechanism 13 in its circumference direction. In this example, as indicated by arrows in FIGS. 2 and 3, the rotary table 12 is rotated in a clockwise direction in a planar view. Six circular concave portions 14 are formed on a surface of the rotary table 12 in the circumferential direction. The wafer W is horizontally loaded onto each of the concave portions 14. In the figures, the numeral “15” is a through-hole formed in the concave portion 14. Further, a ring-shaped groove 16 configured to surround each of the concave portions 14 is formed on the surface of the rotary table 12.

Exhaust ports 17, 18 are opened at the bottom of the vacuum chamber 11 outside the rotary table 12. One end of an exhaust pipe 21 is connected to each of the exhaust ports 17 and 18. The other end of the exhaust pipe 21 is connected to an exhaust mechanism 23 via an exhaust amount adjustment unit 22. The exhaust mechanism 23 may be formed of a vacuum pump, for example. The exhaust amount adjustment unit 22 may include a value. Further, the exhaust amount adjustment unit 22, for example, adjusts an exhaust flow rate from the exhaust ports 17 and 18, and maintains the inside of the vacuum chamber 11 under a vacuum atmosphere of a predetermined pressure.

In FIG. 2, the numeral “24” is a conveyance door of the wafer W. The conveyance door 24 is opened to a sidewall of the vacuum chamber 11. The numeral “25” is a gate valve for opening/closing the conveyance door 24. In FIG. 1, the numeral “26” is a lifting pin provided at the bottom of the vacuum chamber 11, and the numeral “27” is a lifting mechanism. Through an operation of the lifting mechanism 27, the lifting pins 26 may be projected on the surface of the rotary table 12 through the through-holes 15 of the concave portions 14 placed so as to face the conveyance door 24. Thus, the wafer W can be delivered between the conveyance mechanism 29 of the wafer W illustrated in FIG. 2 and the concave portion 14.

As illustrated in FIG. 2, a gas shower head 3A, a purge gas nozzle 4A, a hood 5A, a gas shower head 3B, a purge gas nozzle 4B, and a hood 5B are sequentially configured in the rotation direction of the rotary table 12 over the rotary table 12. The exhaust port 17 is opened between the gas shower head 3A and the purge gas nozzle 4A when viewed in the circumferential direction of the vacuum chamber 11 so that gases respectively supplied from the gas shower head 3A and the purge gas nozzle 4A are exhausted. The exhaust port 18 is opened between the gas shower head 3B and the purge gas nozzle 4A when viewed in the circumferential direction of the vacuum chamber 11 so that gases respectively supplied from the gas shower head 3B and the purge gas nozzle 4B are exhausted.

The gas shower heads 3A and 3B are raw material gas supply units and likewise configured. The gas shower head 3A illustrated in FIG. 1 is described as a representative example. The gas shower head 3A includes a shower head body 31 provided in the vacuum chamber 11. A plurality of gas discharge ports 32 is opened at the bottom of the shower head body 31. The shower head body 31 includes a flat diffusion space 33 therein. The gas diffusing through the diffusion space 33 is supplied from the gas discharge ports 32 to the entire surface of the wafer W placed under the shower head body 31. In the figures, the numeral “34” is a gas supply pipe extending upward from the diffusion space 33. The gas supply pipe 34 is drawn upward from the ceiling plate of the vacuum chamber 11 and connected to an aminosilane gas supply source 35.

The aminosilane gas supply source 35 forcibly supplies aminosilane (an aminosilane gas) which is a film formation raw material in a gaseous state, to the diffusion space 33 through the gas supply pipe 34 in response to a control signal from a control unit 10, which will be described below. Any gas that may be adsorbed to the wafer W and oxidized to form a silicon oxide film may be used as the aminosilane gas. In this example, a bis(tert-butylamino)silane (BTBAS) gas is supplied as the aminosilane gas. Regions (i.e., first regions) under the shower head bodies 31 of the gas shower heads 3A and 3B over the rotary table 12 are aminosilane adsorption regions 30A and 30B.

The purge gas nozzles 4A and 4B are likewise configured and extend in a diameter direction of the rotary table 12. As illustrated in FIG. 2, the purge gas nozzles 4A and 4B include a plurality of gas discharge ports 41 opened to face downward along the diameter direction. Upstream sides of the purge gas nozzles 4A and 4B are drawn to the outside of the sidewall of the vacuum chamber 11 and respectively connected to N₂ gas supply sources 42. Each of the N₂ gas supply sources 42 forcibly supplies N₂ gas to the purge gas nozzles 4A and 4B in response to a control signal from the control unit 10. The N₂ gas purges excessive aminosilane on the surface of the wafer W. When viewed in the rotation direction of the rotary table 12, a region over the rotary table 12 from a downstream side of the gas shower head 3A in the rotation direction thereof to the purge gas nozzle 4A is called a purge region 40A, where the purging is performed. Further, when viewed in the rotation direction, a region over the rotary table 12 from a downstream side of the gas shower head 3B in the rotation direction to the purge gas nozzle 4B is called a purge region 40B, where the purging is performed.

The hoods 5A and 5B are described below. The hoods 5A and 5B are configured similarly. The hood 5A of FIG. 1 is described as a representative example. The hood 5A includes a main body portion 51 that is circular when seen in a planar view and a passage formation portion 52. The main body portion 51 is provided in the vacuum chamber 11. The passage formation portion 52 is configured to extend toward the outside of the vacuum chamber 11 so that it penetrates the ceiling plate of the vacuum chamber 11 upward from the main body portion 51. Further, a hood lifting mechanism 53 that forms a partition mechanism is connected to the passage formation portion 52 outside the vacuum chamber 11. The hood lifting mechanism is configured to lift the passage formation portion 52 and the main body portion 51. Further, a bellows 52A is provided so as to surround the passage formation portion 52 outside the vacuum chamber 11. The bellows 52A is configured to extend or contract as the hood 5A moves up and down, thus maintaining the inside of the vacuum chamber 11 at vacuum atmosphere. A region where the main body portion 51 over the rotary table 12 moves up and down forms a second region.

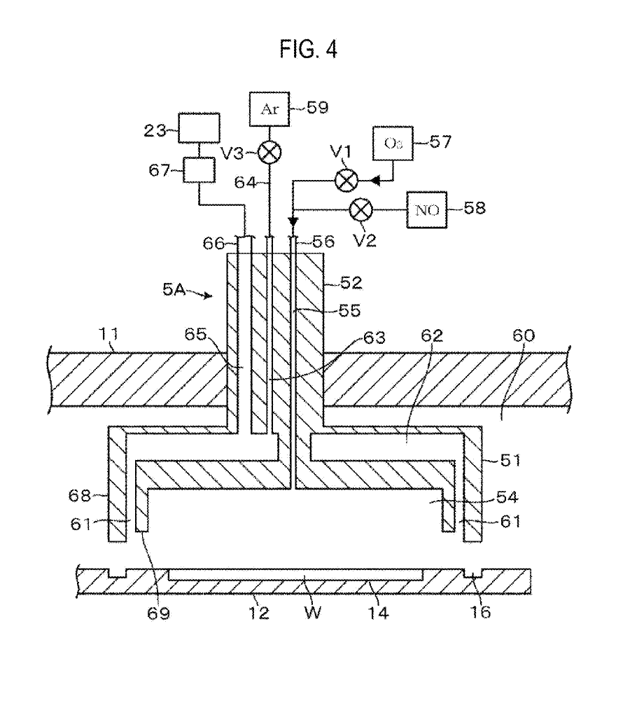

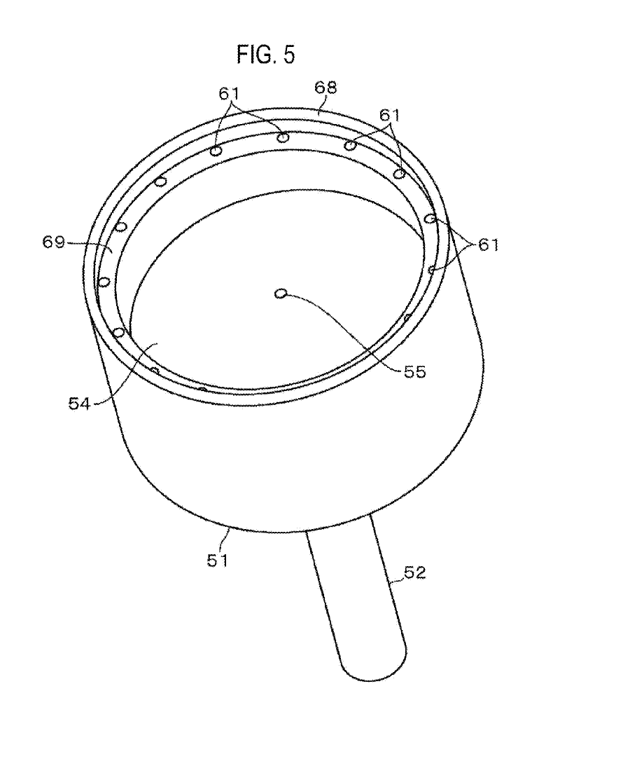

The hood 5A is described below with reference to a longitudinal-section side view and a lower side perspective view of FIGS. 4 and 5. Further, in each of figures including FIGS. 4 and 5 other than FIG. 1, the hood lifting mechanism 53 is not shown for convenience sake. A concave portion that is flat and circular, for example, is formed at the central portion on the lower side of the main body portion 51. The concave portion forms a processing space 54 for performing oxidation of aminosilane adsorbed to the wafer W. In other words, the main body portion 51 is a processing space formation member. A gas supply path 55 is provided in the main body portion 51 so that one end of the gas supply path 55 is opened at the central portion of the processing space 54. The other end of the gas supply path 55 extends upward along the passage formation portion 52, and is connected to a downstream end of a gas supply pipe 56 provided outside the vacuum chamber 11. An upstream end of the gas supply pipe 56 is divided and connected to an ozone (O₃) gas supply source 57 and a nitrogen monoxide (NO) gas supply source 58 that is an energy supply portion, through valves V1 and V2 respectively.

For example, a plurality of openings 61 is opened at an interval along the circumferential direction of the main body portion 51 outside the processing space 54 under the main body portion 51. Each of the openings 61 is connected to a buffer region 62 formed over the processing space 54 in the main body portion 51. The buffer region 62 has a flat ring shape that surrounds the gas supply path 55. One end of a gas supply path 63 is opened in the buffer region 62. The other end of the gas supply path 63 extends upward along the passage formation portion 52, and is connected to a downstream end of a gas supply pipe 64 provided outside the vacuum chamber 11. An upstream end of the gas supply pipe 64 is connected to an argon (Ar) gas supply source 59 through a valve V3. Each of the Ar gas supply source 59, the O₃ gas supply source 57, and the nitrogen monoxide (NO) gas supply source 58 is configured to forcibly supply a gas toward a downstream end of the gas supply pipe in response to a control signal from the control unit 10 which will be described below.

Further, one end of an exhaust path 65 is opened in the buffer region 62. The other end of the exhaust path 65 extends upward along the passage formation portion 52, and is connected to an upstream end of an exhaust pipe 66 provided outside the vacuum chamber 11. A downstream end of the exhaust pipe 66 is connected to the exhaust mechanism 23 through the exhaust amount adjustment unit 67 configured in the same manner as the exhaust amount adjustment unit 22. An exhaust amount of the buffer region 62 is controlled by the exhaust amount adjustment unit 67. Further, as illustrated in FIG. 1, the gas supply pipes 56 and 64 and the exhaust pipe 66 are respectively connected to the passage formation portion 52 through the bellows 50 so as not to hinder the lifting of the hood 5A. In the figures other than FIG. 1, the bellows 50 is not shown.

An annular-shaped protrusion 68 protruded downward is formed in the main body portion 51. The protrusion 68 is formed to surround the opening 61 and the processing space 54. When the main body portion 51 moves down, the protrusion 68 is engaged with the groove 16 of the rotary table 12 so that the processing space 54 can be airtightly maintained. In the figures, the numeral “69” is a bottom surface inside the protrusion 68 of the main body portion 51. Further, for convenience of description, the outside of the processing space 54 within the vacuum chamber 11 may be described as an adsorption space 60 where the adsorption of aminosilane is performed.

The O₃ gas supply source 57 as an atmosphere gas supply unit is further described below. For example, the O₃ gas supply source 57 is configured to supply an O₃ gas having a ratio of 8 to 100 Vol. % to oxygen to the processing space 54. As will be described below in detail, in the embodiment, ozone is decomposed by supplying an NO gas in the state while the processing space 54 into which the wafer W is carried is maintained under an ozone atmosphere. Such a decomposition is a forcibly generated chain decomposition reaction where ozone is decomposed by NO to generate active species, such as oxygen radicals, and the active species decompose ambient ozone to further generate the active species of oxygen. In other words, when the NO gas is supplied to the processing space 54, in the pressure of the processing space 54, O₃ of a concentration equal to or higher than a concentration at which the chain decomposition reaction occurs needs to be present in the processing space 54. In order to form such an atmosphere in the processing space 54, the O₃ gas is supplied from the O₃ gas supply source 57.

The film formation apparatus 1 includes the control unit 10. For example, the control unit 10 includes a computer including a CPU and a memory unit (not illustrated). The control unit 10 sends a control signal to each element of the film formation apparatus 1 for controlling each of operations, such as opening/closing of each valve V, adjusting an exhaust flow rate by the exhaust amount adjustment units 22 and 67, supplying a gas from each gas supply source to each gas supply pipe, lifting of the lifting pins 26 by the lifting mechanism 27, rotating the rotary table 12 by the rotation mechanism 13, and lifting of the hoods 5A and 5B by the hood lifting mechanism 53. Further, in order to output such a control signal, a program formed of a group of steps (or commands) is stored in the memory unit. The program may be stored in a storage medium, such as, a hard disk, a compact disk, a magnet optical disk, or a memory card and installed in the computer.

Processes performed by the film formation apparatus 1 are schematically described below. When the rotary table 12 is rotated, the wafer W sequentially and repeatedly moves through the aminosilane adsorption region 30A, the purge region 40A, a region in which the processing space 54 is formed by the hood 5A, the aminosilane adsorption region 30B, the purge region 40B, and a region in which the processing space 54 is formed by the hood 5B. Assuming a cycle including adsorbing the aminosilane to the wafer W, purging the excessive aminosilane on the surface of the wafer W, and oxidizing the aminosilane (i.e., the formation of a silicon oxide layer) adsorbed to the wafer W form a single cycle, the cycle is repeatedly performed a plurality number of times as the wafer W moves through the regions as described above. Thus, the silicon oxide layer is stacked on the wafer W to form a silicon oxide film.

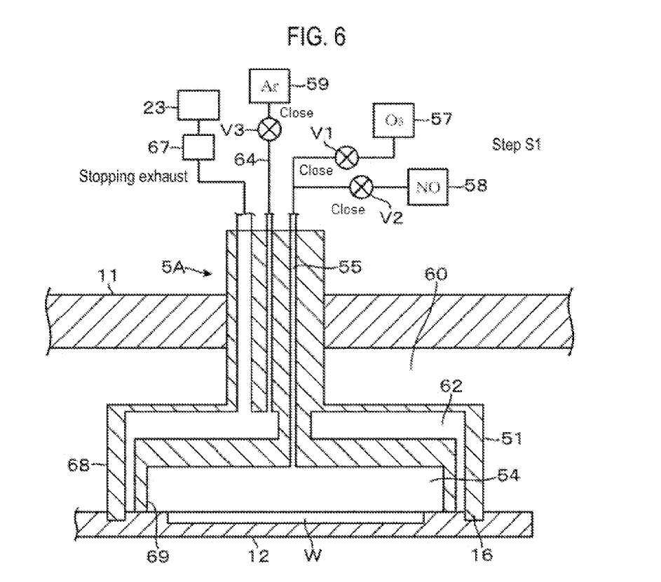

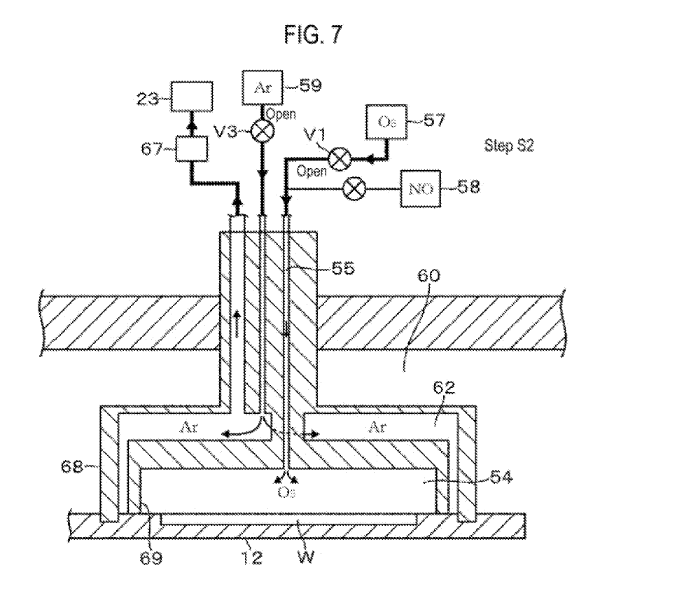

The hoods 5A and 5B likewise perform the oxidation of aminosilane. A process of oxidizing aminosilane by the hood 5A is described below with reference to FIGS. 6 to 10. In FIGS. 7 to 10, a gas flow in the processing space 54 of the hood 5A and the buffer region 62 is indicated by an arrow. Further, a thicker arrow is indicated when a gas flows in the gas supply pipe and the exhaust pipe than when a gas does not flow in the gas supply pipe and the exhaust pipe. Further, character “open” or “close” is attached near the valve in order to indicate the open/close state of the valve, if necessary. When the wafer W is processed by the hood 5A, a pressure in the adsorption space 60 within the vacuum chamber 11 becomes, for example, 1 Torr (0.13×10³ Pa) to 10 Torr (1.3×10³ Pa) by the exhaust from the exhaust ports 17 and 18. Such a pressure is pressure for performing the adsorption without generating particles from an aminosilane gas. In this processing example, the pressure is assumed to be 3 Torr (0.39×10³ Pa).

When the rotary table 12 is rotated and thus the wafer W moved from the purge region 40A is placed under the main body portion 51 of the hood 5A, the rotation of the rotary table 12 is stopped. At this time, each of the valves V1 to V3 of the hood 5A is closed. Further, the exhaust of the buffer region 62 by the exhaust amount adjustment unit 67 is stopped. After the rotation of the rotary table 12 is stopped, the main body portion 51 moves down. Thus, the protrusion 68 enters the groove 16 of the rotary table 12, and is engaged with the groove 16. Accordingly, the processing space 54 of the main body portion 51 becomes airtight, while being isolated from the adsorption space 60. When the main body portion 51 further moves down, the bottom 69 of the main body portion 51 is closely attached to the surface of the rotary table 12 such that the processing space 54 is partitioned from the buffer region 62 (Step S1 of FIG. 6).

Thereafter, the valve V1 is opened, an O₃ gas is supplied to the gas supply path 55 and the processing space 54, and an O₃ concentration in the gas supply path 55 and the processing space 54 increases. The valve V3 is opened and an Ar gas is supplied to the buffer region 62 simultaneously with the supply of the O₃ gas, and the buffer region 62 is exhausted by the exhaust amount adjustment unit 67 (Step S2 of FIG. 7). When pressure in the gas supply path 55 and the processing space 54 becomes, for example, 50 Torr, the valve V1 is closed, and the O₃ gas is sealed in the gas supply path 55 and the processing space 54. At this time, an ozone concentration in the gas supply path 55 and the processing space 54 becomes equal to or higher than a limit at which the aforementioned chain decomposition reaction is generated when an NO gas is supplied to the processing space 54 through the passage formation portion 52 in a subsequent step. Further, a pressure in the buffer region 62 becomes, for example, 50 Torr (6.5×10³ Pa) that is the same as that within the processing space 54.

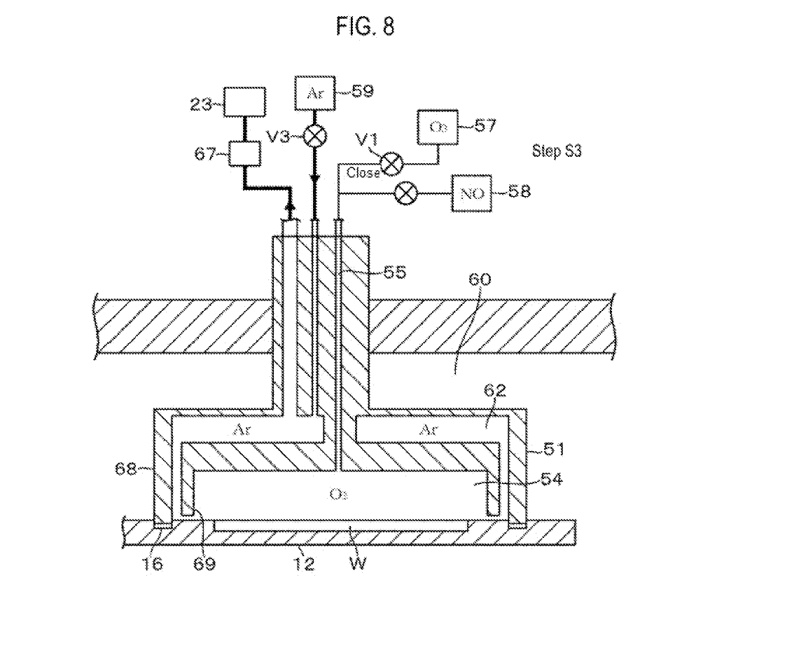

Thereafter, when the main body portion 51 slightly moves up and the bottom 69 of the main body portion 51 rises from the surface of the rotary table 12, a gap is formed. The processing space 54 communicates with the buffer region 62 through the gap (Step S3 of FIG. 8). At this time, the protrusion 68 rises from the bottom of the groove 16 of the table 12, but is received in the groove 16. Thus, the processing space 54 continues to be isolated from the adsorption space 60, and is airtightly maintained. Although the processing space 54 and the buffer region 62 communicate with each other as described above, the pressure in the buffer region 62 is the same as that in the processing space 54, thus suppressing both an inflow of the Ar gas from the buffer region 62 to the processing space 54 and an inflow of the O₃ gas from the processing space 54 to the buffer region 62. In other words, although the gap is formed, the O₃ gas remains sealed in the processing space 54 such that a concentration of the O₃ gas in the gas supply path 55 and the processing space 54 is maintained at a concentration equal to or higher than a limit at which the chain decomposition reaction is generated.

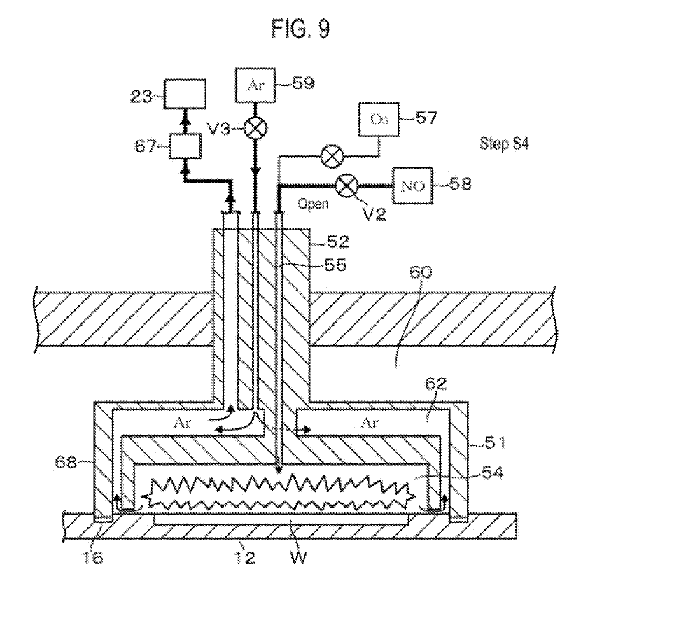

Thereafter, when the valve V2 is opened, an NO gas is supplied to the gas supply path 55. The supplied NO gas comes in contact with O₃ in the gas supply path 55, thereby igniting O₃. As a result, a forcible decomposition reaction (i.e., a combustion reaction) of O₃ is generated as already described. Chain decomposition proceeds within a region ranging from the gas supply path 55 to the processing space 54 within a very short time, thus generating active species of oxygen. The active species of oxygen react with a molecule layer of aminosilane adsorbed to the surface of the wafer W, thereby oxidizing aminosilane. Thus, a molecule layer formed of silicon oxide is formed. Since the forced chain decomposition of ozone proceeds instantaneously, the amount of the active species is suddenly increased within the processing space 54. In other words, the gas is suddenly expanded within the processing space 54. However, since the processing space 54 and the buffer region 62 communicate with each other as described above, the expanded gas flows into the buffer region 62, thereby preventing the pressure in the processing space 54 from becoming excessive (Step S4 of FIG. 9).

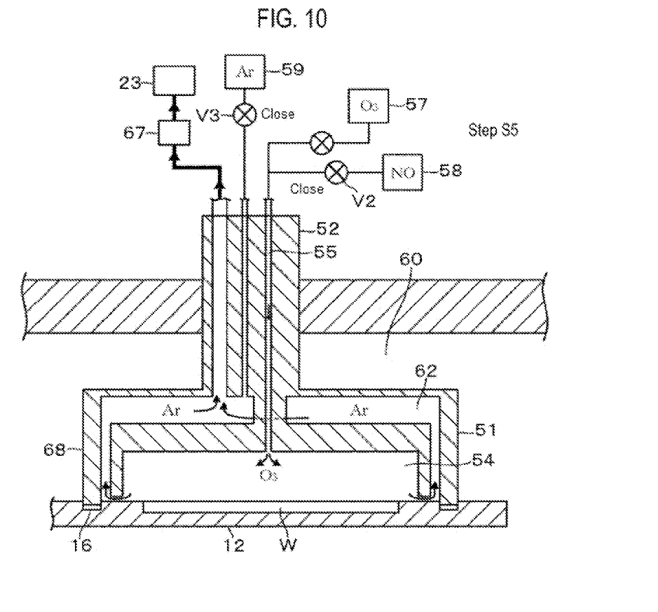

Since the active species are unstable, the active species are changed into oxygen in, for example, several milliseconds after the active species are generated. Thus, the oxidation of aminosilane is terminated. The valves V2 and V3 are closed, and the buffer region 62, the processing space 54, and the gas supply path 55 are exhausted, thereby removing remaining oxygen (Step S5 of FIG. 10). Thereafter, the exhaust by the exhaust amount adjustment unit 67 is stopped, and the main body portion 51 moves up. As the protrusion 68 of the main body portion 51 exits from the groove 16 of the rotary table 12, the engagement between the protrusion 68 and the groove 16 are released. Thus, the processing space 54 is opened to the adsorption space 60. Further, the main body portion 51 is stopped at a location illustrated in FIG. 4 (Step S6). Thereafter, the rotary table 12 is rotated, and the wafer W moves toward the aminosilane adsorption region 30B under the gas shower head 3B.

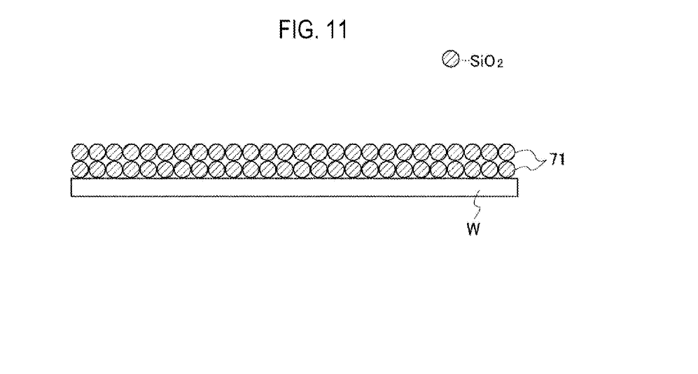

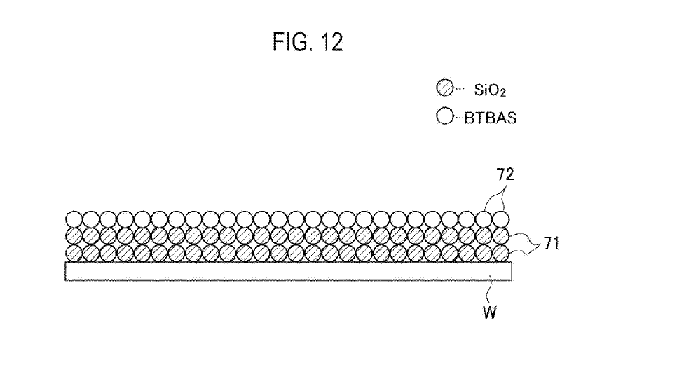

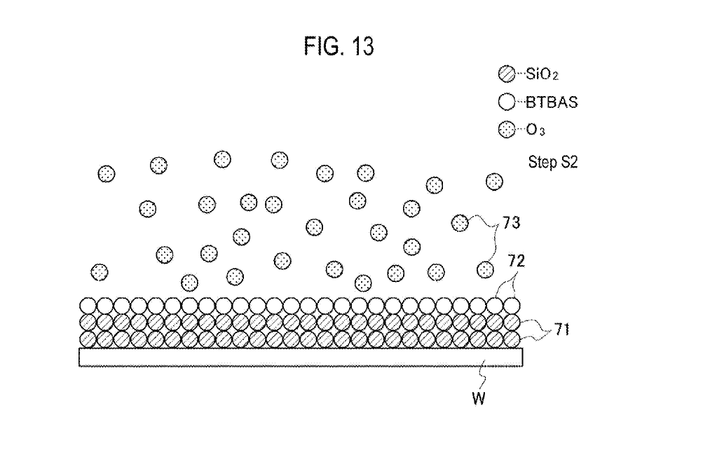

Assuming that one cycle includes the adsorption of aminosilane to the wafer W, the purging of aminosilane, and the oxidation of aminosilane as described above, a change in the state of the surface of the wafer W in a cycle after a second cycle is described with reference to diagrams of FIGS. 11 to 16. FIG. 11 illustrates a state before a cycle is started, and FIG. 12 illustrates a state in which molecules 72 of aminosilane (BTBAS) is adsorbed to the surface of the wafer W. In each figure, the numeral “71” denotes molecules that form a silicon oxide layer already formed in the wafer W. As described above with reference to Step S2 of FIG. 7, FIG. 13 illustrates a state in which an ozone gas is supplied to the processing space 54 and the gas supply path 55, and the numeral “73” denotes molecules of ozone.

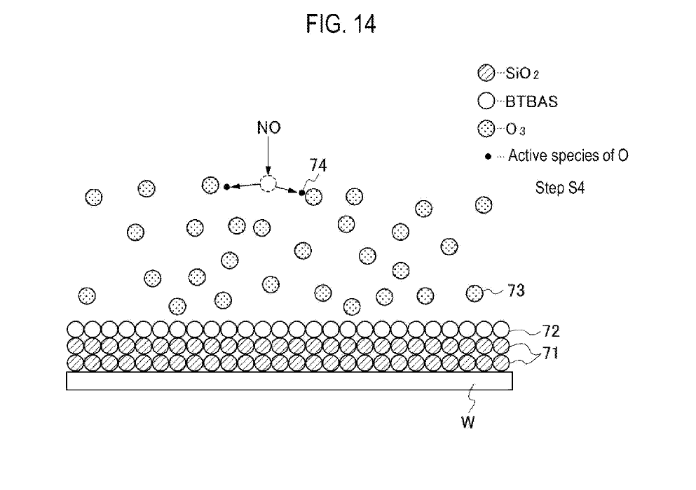

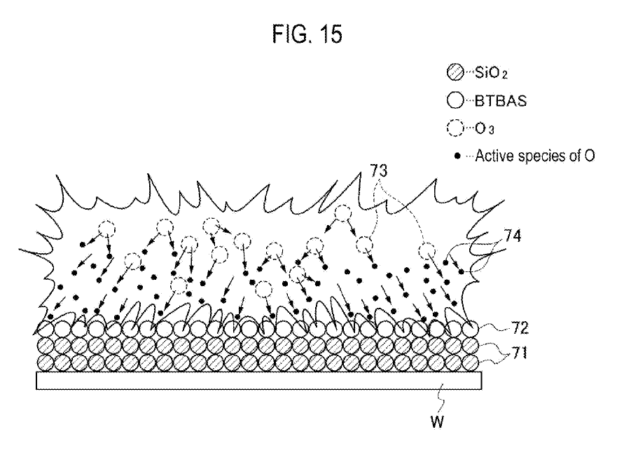

FIG. 14 illustrates the moment when the NO gas is supplied to the gas supply path 55 in subsequent Step S4. As described above, as NO and ozone are chemically reacted energy is applied to ozone. Thus, ozone is forcibly decomposed to generate active species 74 of oxygen. Then, ozone is forcibly decomposed by the active species 74, while generating active species 74, which will further decompose ozone. As already described, such a series of the chain decomposition reactions proceed momentarily, thereby generating the active species 74 (FIG. 15).

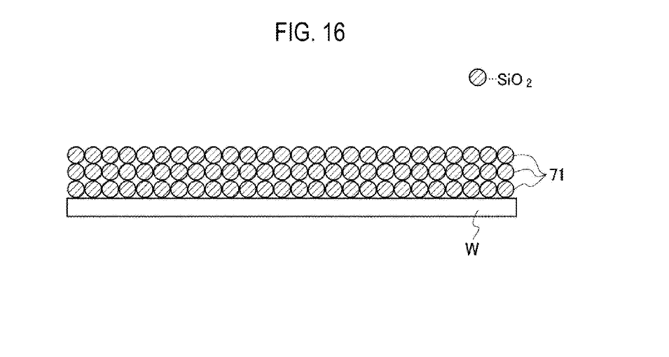

Further, heat and light energy emitted due to the chain decomposition reaction are applied to the molecules 72 of aminosilane exposed to the processing space 54 in which the chain decomposition reaction of ozone is generated. Thus, the energy of the molecules 72 momentarily rises, so a temperature of the molecules 72 rises. Further, since the active species 74 capable of reacting with the molecules 72 are present around the molecules 72 of aminosilane activated as the temperature rises as described above, the molecules 72 react with the active species 74 of oxygen. In other words, the molecules 72 of aminosilane are oxidized, thereby generating molecules 71 of silicon oxide (FIG. 16).

Since the energy generated by the chain decomposition reaction of ozone is applied to the molecules 72 of aminosilane, the oxidation of aminosilane can be performed while the wafer W is not heated using a heater. FIGS. 11 to 16 illustrate the state in which the molecules 72 of aminosilane are oxidized in a cycle after the cycle described with above is repeated twice. As described above, in a first cycle, energy due to the decomposition of ozone is applied to the molecules 72 of aminosilane, thereby oxidizing the molecules 72.

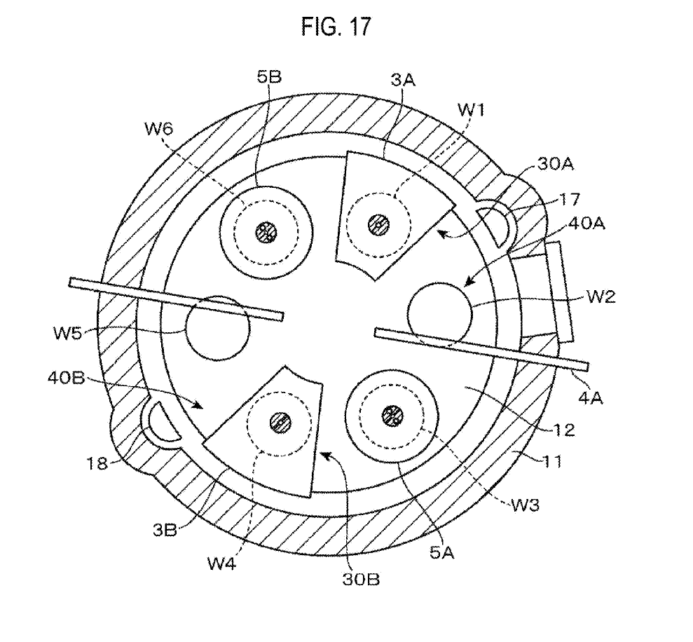

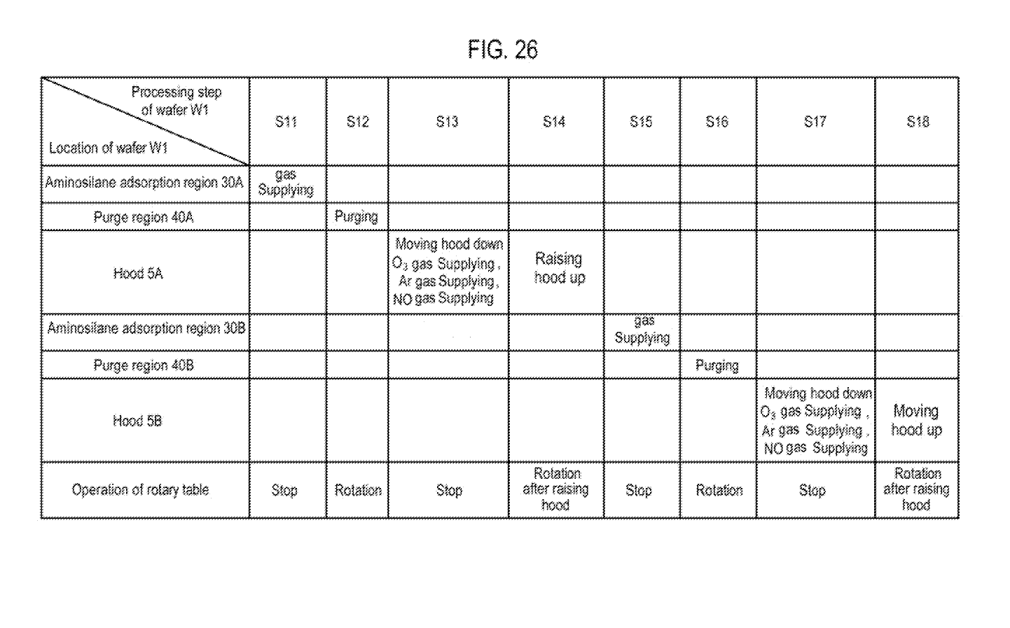

An overall operation of the film formation apparatus 1 is described below with reference to FIGS. 17 to 25. In describing the operation, in order not to complicate description, symbols W1 to W6 are sequentially assigned in a clockwise direction to the wafers W loaded onto the rotary table 12. Further, a chart in which a location of the wafer W1 that is a representative example of the wafers W1 to W6, processes performed at the location, a sequence of the processes, and a rotation state of the rotary table 12 are illustrated in FIG. 26.

FIG. 17 illustrates a state before processes start. In this state, the rotary table 12 is stopped, the wafers W1 and W4 are placed in the aminosilane adsorption regions 30A and 30B under the gas shower heads 3A and 3B, respectively, and the wafers W3 and W6 are placed under the hoods 5A and 5B, respectively. In this state, an N₂ gas is supplied from the purge gas nozzles 4A and 4B while the exhaust by the exhaust ports 17 and 18 being performed, and a pressure inside the vacuum chamber 11 becomes, for example, 3 Torr, as described above. The N₂ gas supplied from the purge gas nozzle 4A is exhausted from the exhaust port 17 close to the purge region 40A through the purge region 40A. The N₂ gas supplied from the purge gas nozzle 4B is exhausted from the exhaust port 18 close to the purge region 40B through the purge region 40B.

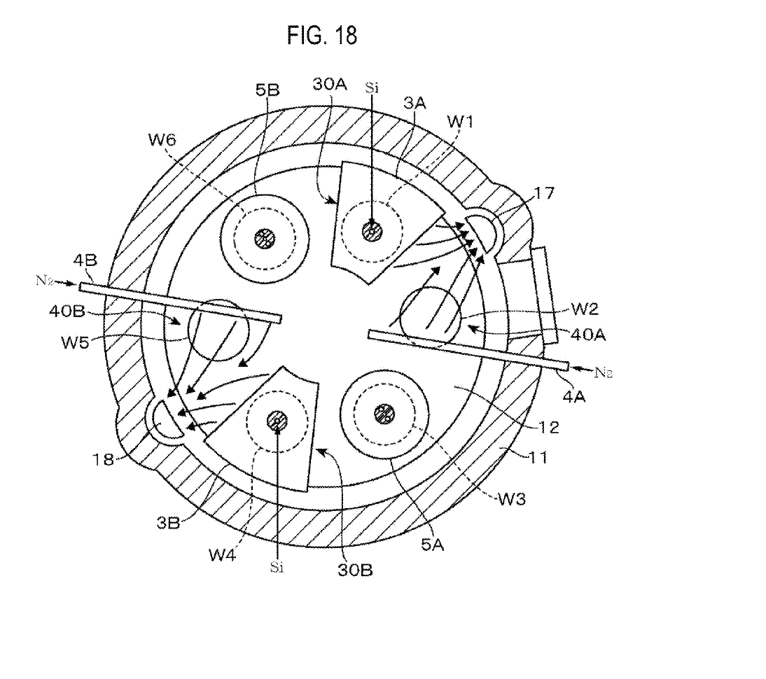

Further, aminosilane gases are supplied from the gas shower heads 3A and 3B to the aminosilane adsorption regions 30A and 30B, respectively, and aminosilane is adsorbed to the surfaces of the wafers W1 and W4 (Step S11 of FIGS. 18 and 26). Excessive aminosilane gases supplied from the gas shower heads 3A and 3B to the wafers W1 and W4 are respectively exhausted from the exhaust ports 17 and 18 near the respective gas shower heads 3A and 3B.

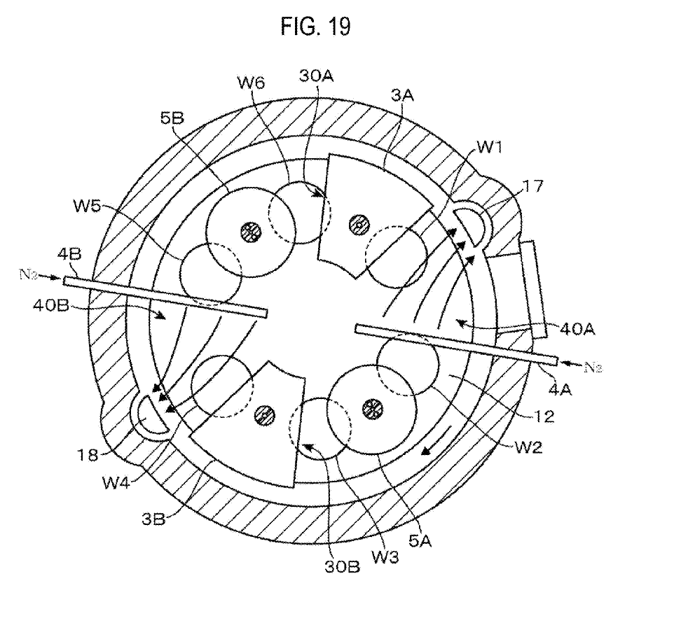

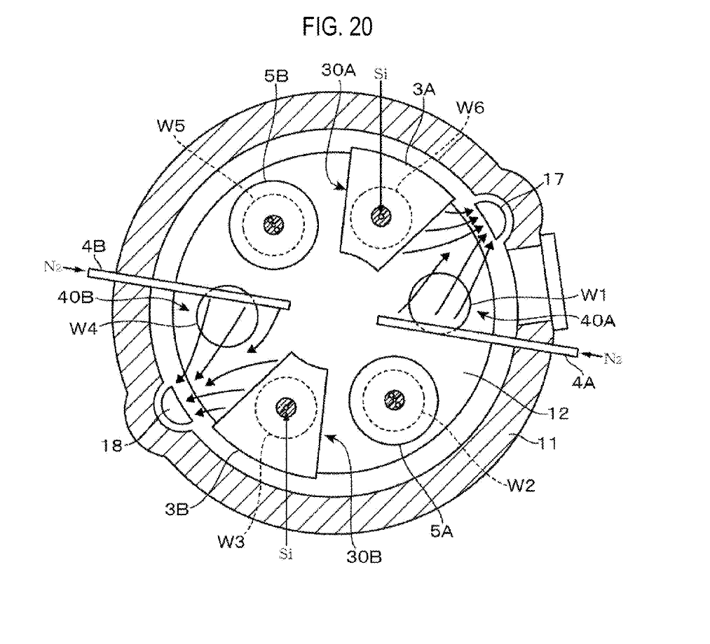

The supply of the aminosilane gas to the aminosilane adsorption regions 30A and 30B is stopped, and the rotary table 12 is rotated. The wafers W1 and W4 move to the purge regions 40A and 40B respectively, and excessive aminosilane on the surfaces thereof are purged (Step S12 of FIGS. 19 and 26). The rotary table 12 continues to rotate. When the wafers W6 and W3 are respectively placed in the aminosilane adsorption regions 30A and 30B, the rotation of the rotary table 12 is stopped, the aminosilane gas is supplied to the aminosilane adsorption regions 30A and 30B, and aminosilane is adsorbed to the wafers W3 and W6 (FIG. 20). Further, after the supply of the aminosilane gas to each of the aminosilane adsorption regions 30A and 30B is stopped, the rotary table 12 is rotated, the wafers W6 and W3 move to the purge regions 40A and 40B respectively, and excessive aminosilane is purged from the wafers W3 and W6. Thereafter, when the wafers W1 and W4 are respectively placed under the hoods 5A and 5B while the wafers W5 and W2 being respectively placed in the aminosilane adsorption regions 30A and 30B, the rotation of the rotary table 12 is stopped.

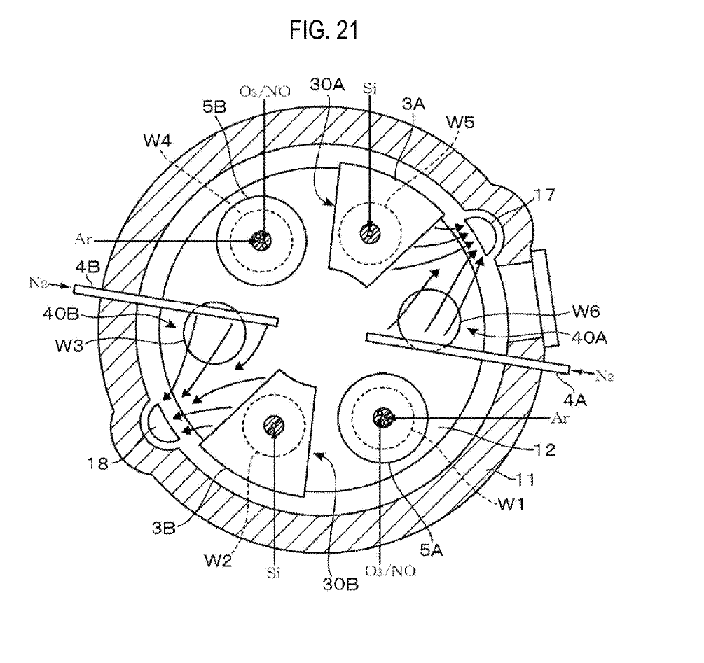

The aminosilane gas is supplied to the aminosilane adsorption regions 30A and 30B, and aminosilane is adsorbed to the wafers W5 and W2. While the aminosilane gas is being supplied, lowering of the hoods 5A and 5B, supply of the O₃ gas to the processing space 54 of each of the hoods 5A and 5B, supply of the Ar gas to the buffer region 62, communication between the processing space 54 and the buffer region 62, and supply of the NO gas to the processing space 54 are sequentially performed (Step S13 of FIGS. 21 and 26). In other words, Step S1 to Step S4 described with reference to FIGS. 6 to 9 are performed, so a silicon oxide layer is made of aminosilane adsorbed to the wafers W1 and W4 by the chain decomposition reaction.

Thereafter, the processing space 54 and the buffer region 62 are exhausted, and the hoods 5A and 5B rise. In other words, Step S5 illustrated in FIG. 10 and Step S6 (not illustrated) described above are performed. While a series of Step S1 to Step S6 are being performed, the supply of the aminosilane gas to each of the aminosilane adsorption regions 30A and 30B is stopped. Then, the hoods 5A and 5B rise, after Step S6 is terminated, the rotary table 12 is rotated (Step S14 of FIG. 26). At this time, the first cycle of the cycle already described above is terminated with respect to the wafers W1 and W4.

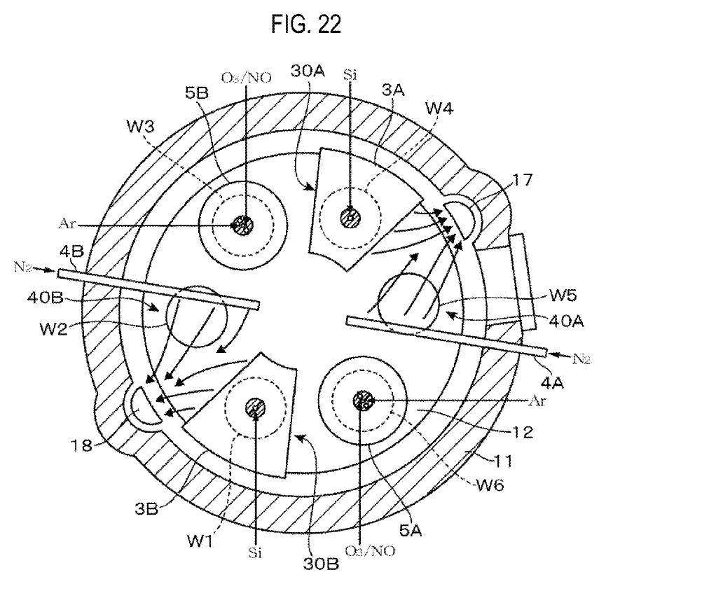

Thereafter, the wafers W5 and W2 respectively move to the purge regions 40A and 40B, and excessive aminosilane on the wafers W5, W2 is purged. Further, when the wafers W4 and W1 are respectively placed under the aminosilane adsorption regions 30A and 30B while the wafers W6 and W3 are respectively placed under the hoods 5A, 5B, the rotation of the rotary table 12 is stopped. Thereafter, Step S1 to Step S6 described above are performed, so aminosilane adsorbed to the wafers W3 and W6 is oxidized. Simultaneously with the oxidation, the supply of the aminosilane gas and stop of the supply of the aminosilane gas are sequentially performed in the aminosilane adsorption regions 30A and 30B. Thus, aminosilane is adsorbed on the already formed silicon oxide layer with respect to the wafers W1 and W4 (Step S15 of FIGS. 22 and 26). In other words, the second cycle of the cycle described above is started with respect to the wafers W1 and W4, and the first cycle is terminated with respect to the wafers W3 and W6.

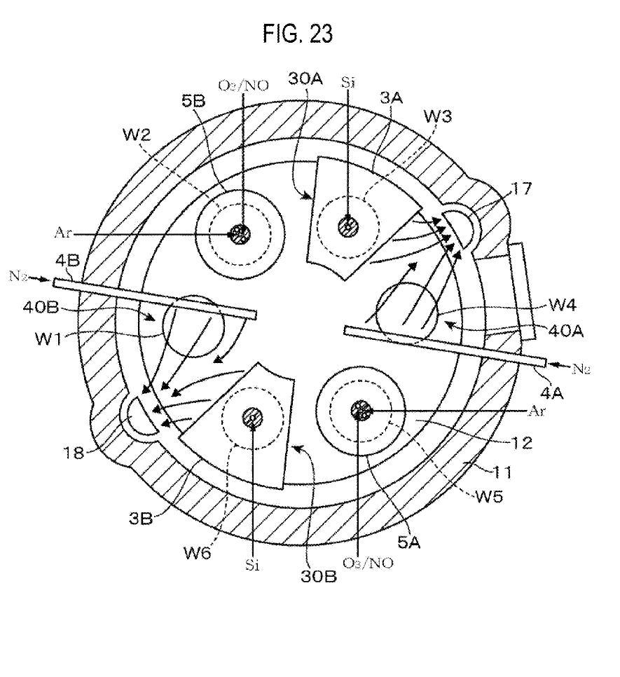

Thereafter, the rotary table 12 is rotated, and the wafers W4 and W1 respectively move to the purge regions 40A and 40B, so excessive aminosilane is purged (Step S16 of FIG. 26). Further, when the wafers W3 and W6 are respectively placed in the aminosilane adsorption regions 30A and 30B while the wafers W5 and W2 are respectively placed under the hoods 5A and 5B, the rotation of the rotary table 12 is stopped. Further, the adsorbed aminosilane is oxidized through Step S1 to Step S6 with respect to the wafers W2 and W5. While Step S1 to Step S6 are being performed, supply of the aminosilane gas and the stop of the supply of the gas in the aminosilane adsorption regions 30A and 30B are sequentially performed, so aminosilane is adsorbed to the wafers W3 and W6 (FIG. 23). In other words, the second cycle of the cycle described above is started with respect to the wafers W3 and W6, and the first cycle is terminated with respect to the wafers W2 and W5.

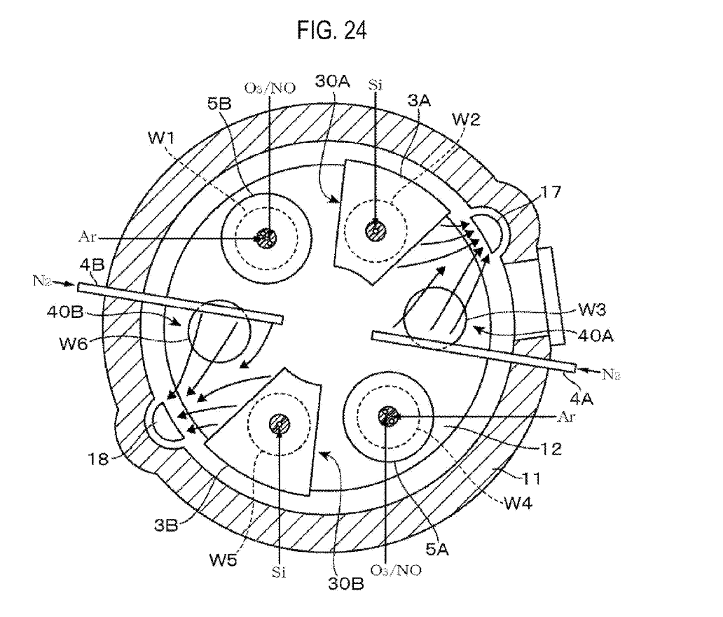

Thereafter, the rotary table 12 is rotated, and the wafers W3 and W6 respectively move to the purge regions 40A and 40B, so excessive aminosilane is purged. Further, when the wafers W2 and W5 are respectively placed in the aminosilane adsorption regions 30A and 30B while the wafers W4, W1 being respectively placed under the hoods 5A and 5B, the rotation of the rotary table 12 is stopped. Further, as described above, the supply of the O₃ gas to the processing space 54 of each of the hoods 5A and 5B, the supply of the Ar gas to the buffer region 62, communication between the processing space 54 and the buffer region 62, and the supply of the NO gas are sequentially performed (Step S17 of FIG. 26). Subsequently, the processing space 54 and the buffer region 62 are exhausted, and the hoods 5A and 5B move up (Step S18 of FIG. 26). In other words, Step S1 to Step S6 described above are performed, and a silicon oxide layer is stacked on the wafers W1 and W4. While Step S1 to Step S6 are being performed, supply of the aminosilane gas and the stop of the supply of the gas in the aminosilane adsorption regions 30A and 30B are sequentially performed, so aminosilane is adsorbed to the wafers W2 and W5 (FIG. 24). After the hoods 5A and 5B move up, the rotary table 12 is rotated. In other words, the second cycle of the cycle described above is started with respect to the wafers W2 and W5, and the second cycle is terminated with respect to the wafers W1 and W4.

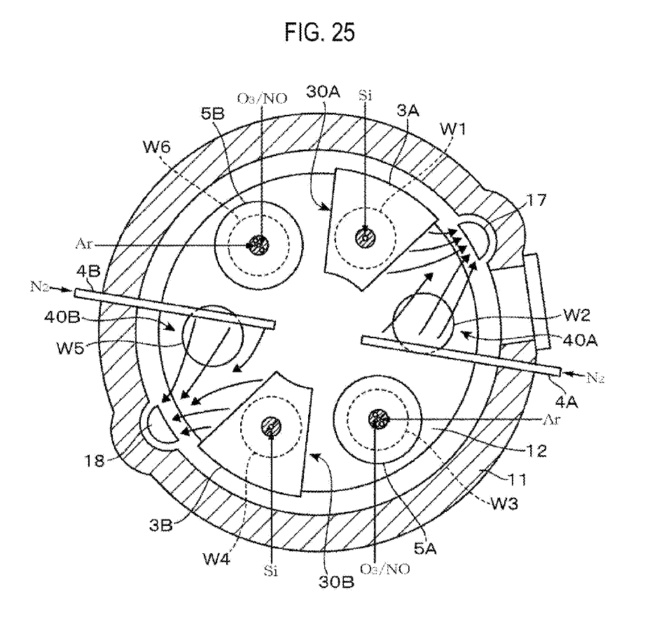

Thereafter, the rotary table 12 is rotated, and the wafers W2 and W5 respectively move to the purge regions 40B and 40A, so excessive aminosilane on the wafers W2, W5 is purged. Further, when the wafers W1 and W4 are respectively placed in the aminosilane adsorption regions 30A and 30B while the wafers W3 and W6 are respectively placed under the hoods 5A and 5B, the rotation of the rotary table 12 is stopped. Further, oxidation in Step S1 to Step S6 is performed on the wafers W3 and W6. Further, aminosilane is adsorbed to the wafers W1 and W4 (FIG. 25). Accordingly, a third cycle of the cycle described above is started with respect to the wafers W1 and W4, and the second cycle is terminated with respect to the wafers W3 and W6.

The details of subsequent processes of the wafer W are omitted, but the wafers W1 to W6 sequentially continue to move through the aminosilane adsorption region 30A or 30B, the purge region 40A or 40B, and the region under the hood 5A or 5B by the rotation of the rotary table 12, and are subject to processes. In this case, while aminosilane is being adsorbed to two of the wafers W1 to W6, oxidation is performed on other two of the wafers W1 to W6. Further, if a silicon oxide film of a predetermined film thickness is formed after a specific number of cycles are performed with respect to each of the wafers W, the wafers W1 to W6 are carried out from the film formation apparatus 1.

In accordance with the film formation apparatus 1 described above, an ozone atmosphere of a relatively high concentration is formed in the processing space 54 formed with the hoods 5A and 5B and the rotary table 12, ozone is subject to chain decomposition by the NO gas at room temperature, and aminosilane on a surface of the wafer W is oxidized by active species generated by the chain decomposition, thereby forming an oxide film. As illustrated in evaluation tests to be described later, the oxide film formed as described above has the same film quality as an oxide film formed by heating the wafer W. Accordingly, a manufacture cost and operation cost for the film formation apparatus 1 can be reduced, because a heater for heating the wafer W in order to perform oxidation does not need to be installed in the film formation apparatus 1. Further, aminosilane can be oxidized without heating the wafer W to a predetermined temperature using the heater. Accordingly, the time required for film formation can be reduced, and throughput can be improved. Further, when the O₃ gas is sealed in the processing space 54 having a relatively small volume and the chain decomposition reaction is performed, the processing space 54 is communicated with the buffer region 62 to which an inert gas is supplied. Therefore, a region in which the chain decomposition reaction is generated is limited to the processing space 54. In other words, a rise of pressure in the processing space 54 can be reduced because a gas suddenly expanded in the processing space 54 is discharged to the buffer region 62. Therefore, damage or deterioration of the wafer W attributable to such a pressure rise can be suppressed. Further, damage or deterioration of the hoods 5A and 5B that form the processing space 54 can be suppressed. In other words, configuration of the film formation apparatus can be simplified because the hoods 5A and 5B do not need to have high pressure resistance, and an increase in the manufacture cost can be suppressed. Further, in the film formation apparatus 1, while aminosilane is being adsorbed to two sheets of the wafers W, oxidation is performed on other two sheets of the wafers W. As such, different processes are simultaneously performed, thus improving productivity of the film formation apparatus.

Further, when an aminosilane gas is supplied to the wafer W, the processing space 54 is partitioned from the buffer region 62. In other words, since the volume of the processing space 54 is suppressed to a small volume, a reduction in the concentration of the aminosilane gas supplied to the processing space 54 can be suppressed. In other words, the aminosilane gas does not need to have a high concentration when aminosilane is adsorbed to the wafer W, thus suppressing an increase in the operation cost of the film formation apparatus.

In the film formation apparatus 1, the gas supply path 55 opened to the processing space 54 is provided to face the surface of the wafer W loaded onto the rotary table 12. The aforementioned decomposition reaction of ozone is instantaneously performed. Since the gas supply path 55 is opened as described above, the decomposition reaction is propagated from the top to the bottom of the processing space 54 within a short time. Since the decomposition reaction is propagated as described above, a downward force is applied to the wafer W. Thus, the wafer W is pressurized toward the rotary table 12 and fixed thereto, and the aforementioned oxidation is performed while the wafer W being fixed to the rotary table 12. In other words, the wafer W can be prevented from deviating from the concave portions 14 of the rotary table 12 due to a change of pressure in the processing space 54 attributable to the chain decomposition reaction of ozone.

Further, the gas supply path 55 is opened at the central part of the processing space 54. Therefore, in the circumferential direction of the processing space 54, a pressure rise is generated with high uniformity due to a chain decomposition reaction. In other words, the pressure is prevented from being heavily applied to a specific place, thus certainly suppressing damages to the hoods 5A and 5B. The shape of the processing space 54 is configured to prevent such a local rise of pressure, but is not limited to the aforementioned example. For example, the processing space 54 may be configured to have a shape of a convex lens protruding upward.

In the examples described above, when the hoods 5A and 5B move up in Step S3 of FIG. 8, the processing space 54 and the buffer region 62 have the same pressure so that a gas flow is prevented from being formed between the processing space 54 and the buffer region 62, thus maintaining the concentration of the O₃ gas in the processing space 54 at a concentration to make sure that the chain decomposition reaction occurs when the NO gas is supplied in Step S4. However, if an ozone concentration in the processing space 54 is maintained so that the chain decomposition reaction may be generated when the NO gas is supplied, a gas flow may be generated between the processing space 54 and the buffer region 62. In other words, when the hoods 5A and 5B move up in Step S3, the pressure in the processing space 54 may be different from that in the buffer region 62.

In the examples described above in order to form an atmosphere in which the chain decomposition reaction is generated, the pressure in the processing space 54 and the gas supply path 55 is set to 50 Torr in Steps S2 and S3, but is not limited thereto. If the chain decomposition reaction is possible, the pressure may be set to be lower than 50 Torr, for example, 20 Torr to 30 Torr. As the pressure in the processing space 54 in Steps S2 and S3 rises, the ozone concentration in the processing space 54 and the gas supply path 55 for generating the chain decomposition reaction is lowered. However, as the pressure in the processing space 54 and the gas supply path 55 in Steps S2 and S3 increases, the pressure in the processing space 54, the gas supply path 55, and the buffer region 62 increases when the chain decomposition reaction occurs. Further, even when the chain decomposition reaction is performed, the processing space 54, the gas supply path 55, and the buffer region 62 are maintained at an atmosphere lower than atmospheric pressure, in other words, a vacuum atmosphere. Accordingly, the pressure in the processing space 54 in Steps S2 and S3 is set so that the hoods 5A and 5B and the wafer W are not damaged.

In the film formation apparatus 1, a spring may be provided between a ceiling within the vacuum chamber 11 and the top of the main body portion 51 of the hoods 5A and 5B. The main body portion 51 is biased to the rotary table 12 by the spring. The hood lifting mechanism 53 is configured to resist a biasing force of the spring and raise the hoods 5A and 5B so that the rotary table 12 may be rotated. In Step S1 to Step S3 described above, the main body portion 51 is biased to the rotary table 12 by the spring and closely attached to the rotary table 12. As a result, the processing space 54 is partitioned from the adsorption space 60. Further, in Step S4, when pressure in the processing space 54 rises due to the chain decomposition reaction, the hoods 5A and 5B resist the biasing force of the spring by such a rise in the pressure and rise to the height at which the buffer region 62 and the processing space 54 communicate with each other as illustrated in FIG. 9. Even in such a configuration, a rise of pressure in the processing space 54 can be reduced because a gas in the processing space 54 can be diffused into the buffer region 62 when the chain decomposition reaction is generated. Thereafter, when the exhaust in Step S5 is performed, the main body portion 51 is placed at the height at which the processing space 54 and the buffer region 62 communicate with each other as illustrated in FIG. 10. After the exhaust is terminated, in Step S6, the main body portion 51 is moved to a location illustrated in FIG. 4 by the hood lifting mechanism 53 so that the rotary table 12 may be rotated.

In the film formation apparatus 1, a switching between a state where the processing space 54 is communicated with the buffer region 62 and a state where the processing space 54 is partitioned from the buffer region 62 is performed by moving up and down the hoods 5A and 5B with respect to the rotary table 12. In some embodiments, the switching may be performed by providing a lifting mechanism for moving up and down the rotary table 12 with respect to the hoods 5A and 5B. In some embodiments, a rotation mechanism for rotating the gas shower heads 3A and 3B, the purge gas nozzles 4A and 4B, and the hoods 5A and 5B with respect to the table 12 may be provided without rotating the rotary table 12. The wafer W may be moved by the rotation mechanism among the aminosilane adsorption regions 30A and 30B, the purge regions 40A and 40B, and the regions under hoods 5A and 5B such that the wafer W is subject to each of the processes described above. In some embodiments, the processing space 54 may be partitioned by forming the protrusion 68 for partitioning the processing space 54 in the rotary table 12 and forming the groove 16 in the hoods 5A and 5B.

In Steps S3 and S4, in other words, when the processing space 54 is communicated with the buffer region 62 and the chain decomposition reaction is generated, the Ar gas may be sealed in the buffer region 62 without supplying the Ar gas to the buffer region 62 and performing the exhaust from the buffer region 62. Further, the gas supplied to the buffer region 62 may be any inert gas, or may be an N₂ gas etc. Further, an NO gas supply passage and an O₃ gas supply passage do not need to be common as in the above example, but may be individually provided.

### Second Embodiment

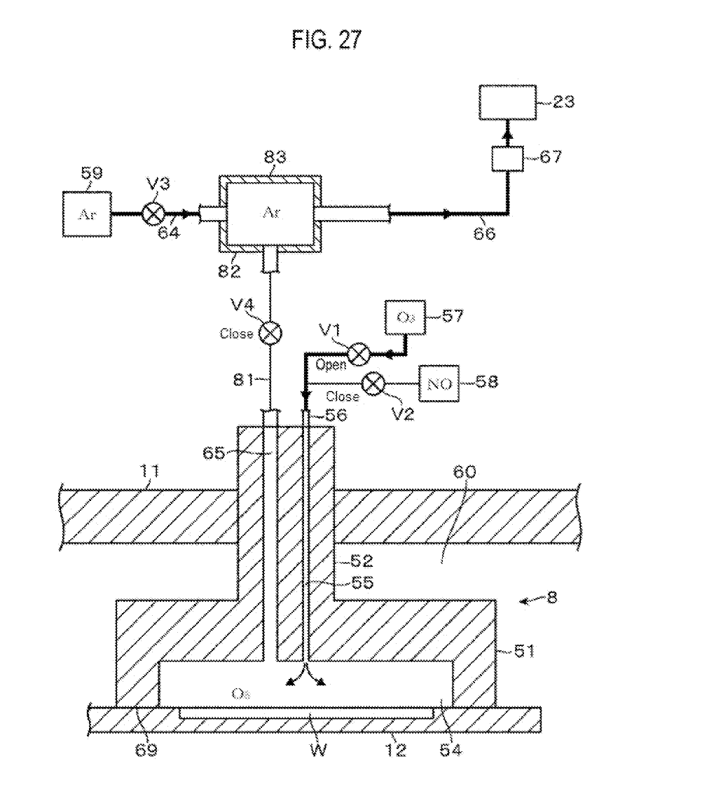

Subsequently, a film formation apparatus in accordance with a second embodiment of the present disclosure is described below. The film formation apparatus includes a hood 8 illustrated in FIG. 27 instead of the hoods 5A and 5B. Description will be made mainly based on differences between the hood 8 and the hoods 5A and 5B. The protrusion 68, the opening 61, and the buffer region 62 are not formed in the main body portion 51 of the hood 8. Further, since the protrusion 68 is not formed, the groove 16 to be engaged with the protrusion 68 is not formed in the rotary table 12.

Further, one end of the exhaust path 65 provided in the hood 8 is opened to a processing space 54. The other end of the exhaust path 65 is extended upward along a passage formation portion 52 and connected to one end of an exhaust pipe 81 provided outside the vacuum chamber 11. The other end of the exhaust pipe 81 is opened to a buffer region 83 within a buffer tank 82. In other words, the processing space 54 and the buffer region 83 are connected through the exhaust pipe 81. A valve V4 that forms a partition mechanism is provided in the exhaust pipe 81. Further, a downstream end of a gas supply pipe 56 connected to an Ar gas supply source 59 is opened in the buffer region 83. Further, an upstream end of the exhaust pipe 66 is opened to the buffer region 83. Although not illustrated, like the hoods 5A and 5B, the hood 8 may be connected to the hood lifting mechanism 53 and move up and down.

Based on differences between an operation of the hood 8 and the operation of the hood 5A, the operation of the hood 8 is described below. While the main body portion 51 is moved down such that a bottom surface 69 of the main body portion 51 is closely attached to the rotary table 12 and the processing space 54 is airtightly partitioned from an adsorption space 60, an O₃ gas is supplied to the processing space 54, as with the hood 5A. Further, while an Ar gas is being supplied from an Ar gas supply source 59 to the buffer region 83, the buffer region 83 is exhausted by an exhaust amount adjustment unit 67. At this time, the valve V4 is closed, and the processing space 54 and the buffer region 83 are partitioned from each other. FIG. 27 illustrates that the processing space 54 and the buffer region 83 are partitioned from each other.

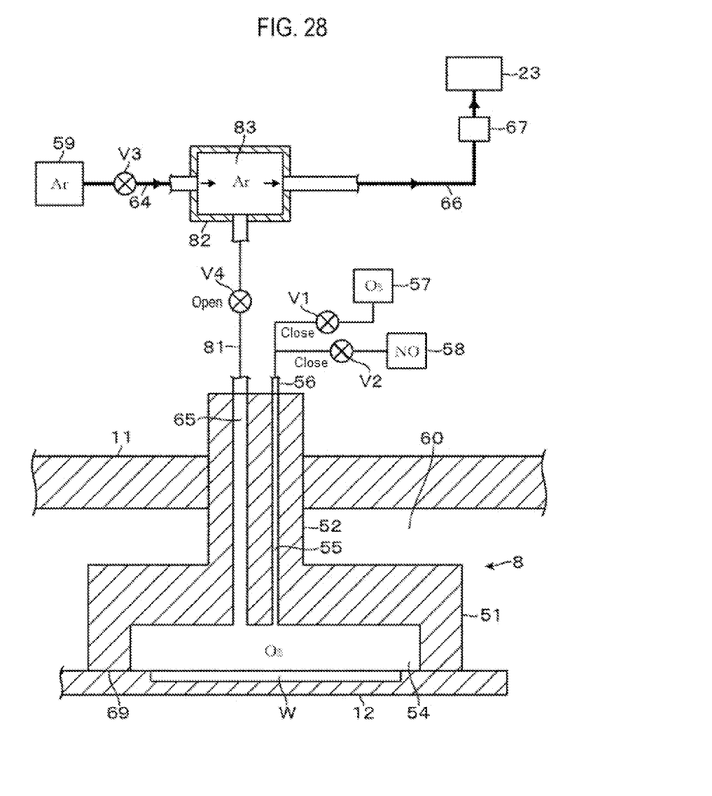

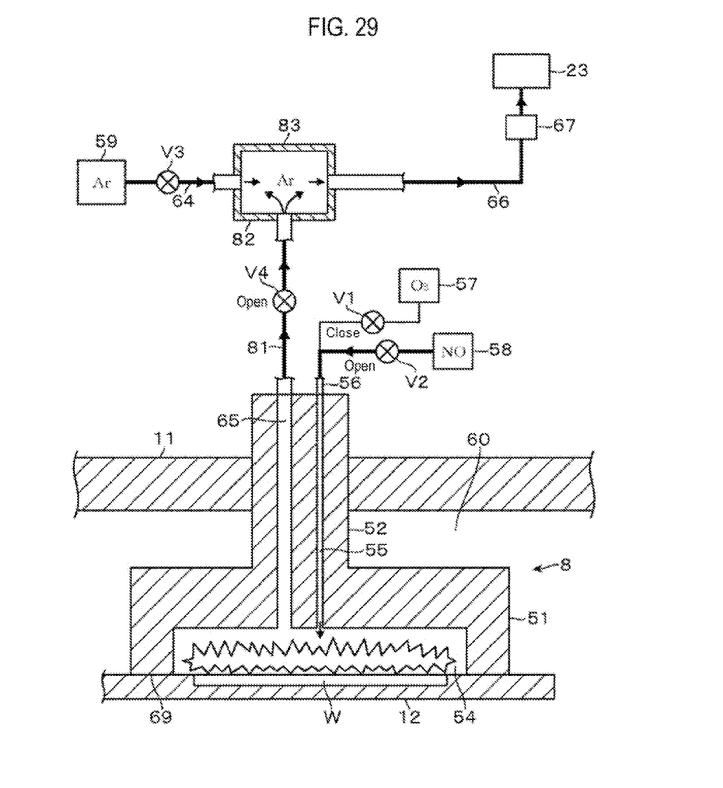

When both of a pressure in the buffer region 83 and a pressure of the processing space 54 become, for example, 50 Torr, the supply of the O₃ gas to the processing space 54 is stopped, and the valve V4 is opened. Thus, the processing space 54 communicates with the buffer region 83. Since the pressure of the processing space 54 is the same as that of the buffer region 83, a gas flow is prevented from being formed between the buffer region 83 and the processing space 54 as in the first embodiment. Thus, an O₃ concentration in the processing space 54 is maintained at a concentration where a chain decomposition reaction can be generated (FIG. 28). Thereafter, as in Step S4 of the first embodiment, an NO gas is supplied to the gas supply path 55 and the processing space 54, thereby generating a chain decomposition reaction of O₃ (FIG. 29). Since the processing space 54 communicates with the buffer region 83 as described above, the reaction products of the processing space 54 may be diffused into the buffer region 83, thus reducing a rise of pressure in the processing space 54.

Thereafter, the valve V3 is closed, the supply of the Ar gas to the buffer region 83 is stopped, and the processing space 54, the gas supply path 55, the exhaust path 65, the exhaust pipe 81, and the buffer region 83 are exhausted, thereby removing reaction products (oxygen) remaining on each of the elements. Thereafter, the exhaust of each of the elements is stopped by the exhaust amount adjustment unit 67, and the hood 8 moves up so that the rotary table 12 may be rotated. Accordingly, since each reaction is performed at room temperature on the film formation apparatus of the second embodiment where the hood 8 is provided, and the rise of pressure in the processing space 54 can be reduced as described above, the same advantages as those of the film formation apparatus 1 of the first embodiment are obtained.

### Third Embodiment

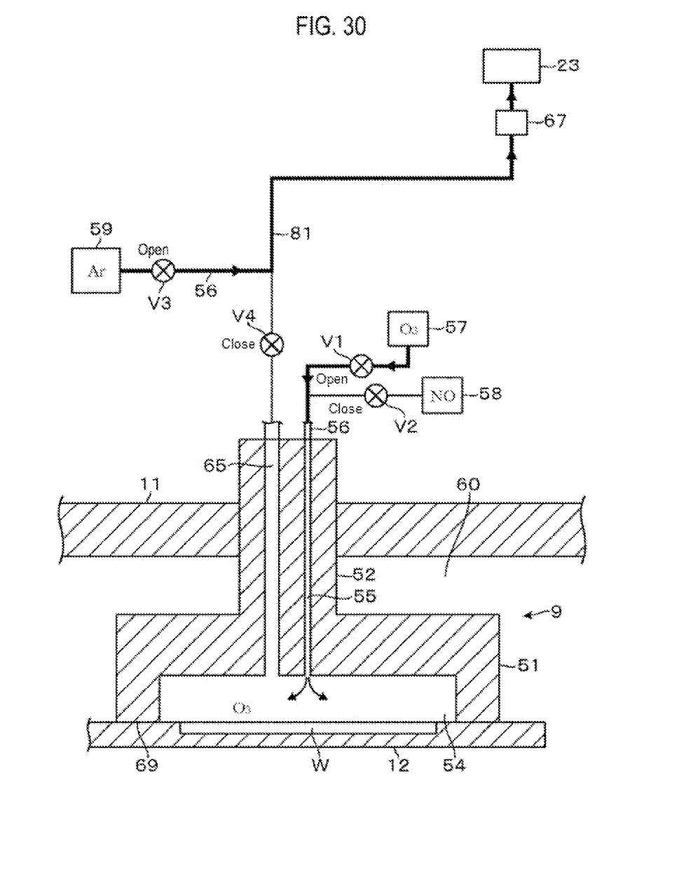

Subsequently, a film formation apparatus of a third embodiment is described below. The film formation apparatus is configured in the same manner as the film formation apparatus described above, except that it includes a hood 9 configured approximately in the same manner as the hood 8. Based on differences between the hood 9 and the hood 8, the hood 9 is described with reference to FIG. 30. The hood 9 is not connected to the buffer tank 82. The downstream end of the exhaust pipe 81 connected to the buffer tank 82 in the second embodiment is connected to the exhaust mechanism 23 sequentially through a valve V4 and an exhaust amount adjustment unit 67. Further, a downstream end of an Ar gas supply pipe 56 is connected between the valve V4 and the exhaust amount adjustment unit 67 in the exhaust pipe 81.

Based on differences between an operation of the hood 9 and the operation of the hood 8, the operation of the hood 9 is described below. While a main body portion 51 is moved down such that a bottom surface 69 of the main body portion 51 is closely attached to a rotary table 12 and the processing space 54 is airtightly partitioned from an adsorption space 60, an O₃ gas is supplied to the processing space 54 as with the hood 8. Further, while an Ar gas is being supplied from the Ar gas supply source 59 to the exhaust pipe 81, an exhaust by the exhaust amount adjustment unit 67 is performed (FIG. 30). At this time, the valve V4 is closed, and the processing space 54 is partitioned from a downstream side of the valve V4 of the exhaust pipe 81.

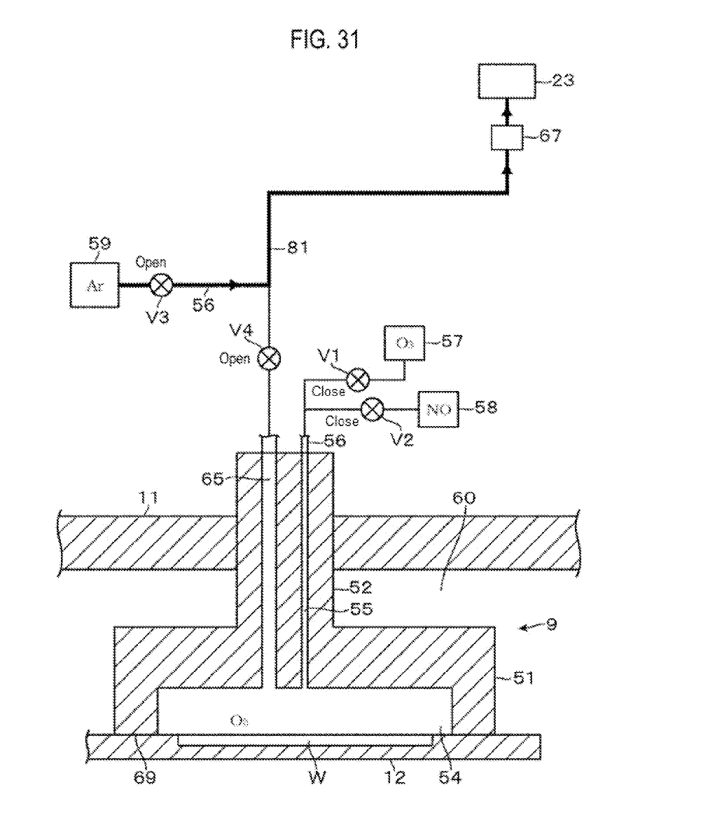

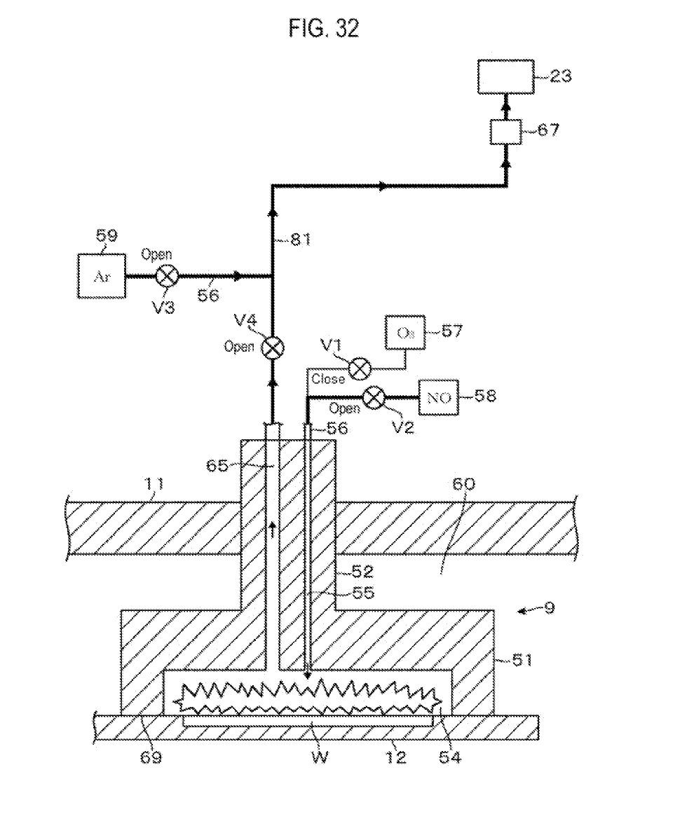

When a pressure in the processing space 54 becomes, for example, 50 Torr, a pressure on the downstream side of the valve V4 of the exhaust pipe 81 also becomes, for example, 50 Torr, the supply of an O₃ gas to the processing space 54 is stopped, and the valve V4 is opened. Thus, the processing space 54 communicates with the downstream side of the valve V4 of the exhaust pipe 81. Since the pressure in the processing space 54 is the same as that on the downstream side of the valve V4 of the exhaust pipe 81, O₃ is sealed in the processing space 54 and an O₃ concentration is maintained at a concentration where a chain decomposition reaction can be generated as in other embodiments (FIG. 31). Thereafter, an NO gas is supplied to the gas supply path 55 and the processing space 54, thereby generating a chain decomposition reaction of O₃ (FIG. 32). As described above, reaction products of the processing space 54 may be diffused into the exhaust pipe 81 as described above, thus reducing a rise of pressure within the processing space 54. In other words, in this example, the downstream side of the valve V4 of the exhaust pipe 81 also functions as the buffer region in the first and the second embodiment.

Thereafter, the valve V3 is closed, the supply of the Ar gas to the exhaust pipe 81 is stopped, and the processing space 54, the gas supply path 55, an exhaust path 65, and the exhaust pipe 81 are exhausted, thereby removing reaction products (oxygen) remaining on each of the elements. Thereafter, the exhaust of each of the elements is stopped by the exhaust amount adjustment unit 67, and the hood 9 moves up so that the rotary table 12 may be rotated. The film formation apparatus of the third embodiment where the hood 9 is installed has the same advantages as the first and the second formation apparatuses.

In each of the aforementioned embodiments, the aforementioned chain decomposition reaction is illustrated as being started by supplying energy to ozone through a chemical reaction between NO and ozone. If energy can be supplied so that the chain decomposition reaction is started, the present disclosure is not limited to the chemical reaction described above. For example, a laser beam radiation unit for radiating a laser beam to the processing space 54 may be provided in each of the hoods or the rotary table 12. Further, the chain decomposition reaction may be started by applying energy to ozone through the radiation of the laser beam. Further, an electrode may be provided in each of the hoods or the rotary table 12, and a discharge may be generated by applying a voltage to the electrode. The chain decomposition reaction may be started by applying energy generated from the discharge. However, from a viewpoint of simplifying the configuration of the film formation apparatus and of preventing a metal forming a discharge electrode from being scattered to the wafer W, the chain decomposition reaction may be generated by the generation of the aforementioned chemical reaction. A gas for applying energy is not limited to the NO gas, but may be any gas capable of generating the aforementioned chain decomposition reaction.

However, for example, in the film formation apparatus 1, the NO gas may be supplied to the processing space 54, while an ammonia gas, a methane gas, or a diborane gas, together with the ozone gas, being supplied to the processing space 54. When O₃ is decomposed, the gases may be also decomposed to chemically react with aminosilane, thereby forming a silicon oxide film doped with elements that form the gases. Specifically, a silicon oxide film doped with nitrogen (N), carbon (C), or boron (B) can be formed by supplying ammonia, a methane gas, or a diborane gas to the processing space 54. If such doping is performed in each of the embodiments, each the gases for the doping is supplied to the processing space 54 until the NO gas is supplied to the processing space 54 after the processing space 54 is airtightly configured. When each of the gases for the doping is supplied, the gas supply pipe 55 provided in each of the hoods may be used.

The raw material gas applied to the embodiments is not limited to the formation of the silicon oxide film as described above. For example, an aluminum oxide, hafnium oxide, strontium oxide, or titanium oxide film may be formed using trimethylaluminum [TMA], tetrakis(ethylmethyl)aminohafnium [TEMHF], strontium bis(tetramethylheptanedionate) [Sr(THD)₂], or titanium methylpentanedionato bis(tetramethylheptanedionate) [Ti(MPD)(THD)].

### Evaluation Test

Evaluation tests performed in relation to the present disclosure are described below. For an evaluation test 1, as described in each embodiment, a silicon oxide film was formed on the wafer W by supplying various gases to the processing space within the vacuum chamber at room temperature and repeatedly performing the aforementioned cycle including the adsorption of aminosilane, the purge of the surface of the wafer W, and the oxidation of aminosilane by the chain decomposition reaction of ozone. Further, the silicon oxide film formed using the film formation apparatus was subjected to wet etching, and an etching rate was measured. In the evaluation test 1, an etching rate on one side of the wafer W was measured, and an etching rate on the other side thereof was measured. Further, unlike the film formation apparatus described in each of the embodiments, the film formation apparatus used in the evaluation test 1 is a sheet-type processing apparatus for carrying a sheet of the wafer W in the vacuum chamber and performing processing on the wafer W, and the region partitioned by the lifting of the hood within the vacuum chamber is not formed

For a comparison test 1-1, a silicon oxide film was formed on the wafer W using a film formation apparatus capable of generating plasma from an oxygen gas in a vacuum chamber. More specifically, like the film formation apparatus used in the evaluation test 1, the film formation apparatus used in the comparison test 1-1 may supply a raw material gas to the vacuum chamber and also generate plasma from the oxygen supplied to the vacuum chamber. Further, the film formation may be conducted by alternately performing the supply of the raw material gas and the oxidization of the raw material gas using the plasma. As in the evaluation test 1, the oxidation was performed at room temperature in the comparison test 1-1. After the film was formed, the silicon oxide film was subjected to wet etching and etching rates were measured as in the evaluation test 1.

For a comparison test 1-2, while the wafer W within the vacuum chamber was being heated to a predetermined temperature using a heater, a silicon oxide film was formed on the wafer W by repeatedly performing alternately supplying the raw material gas for forming a film and supplying an ozone gas to the wafer W. In other words, in the comparison test 1-2, a chain decomposition reaction of ozone was not performed, and thermal energy was applied to the wafer W by heating the wafer W such that aminosilane adsorbed to the wafer W was oxidized by ozone. After the film was formed, etching rates were measured as in other tests.

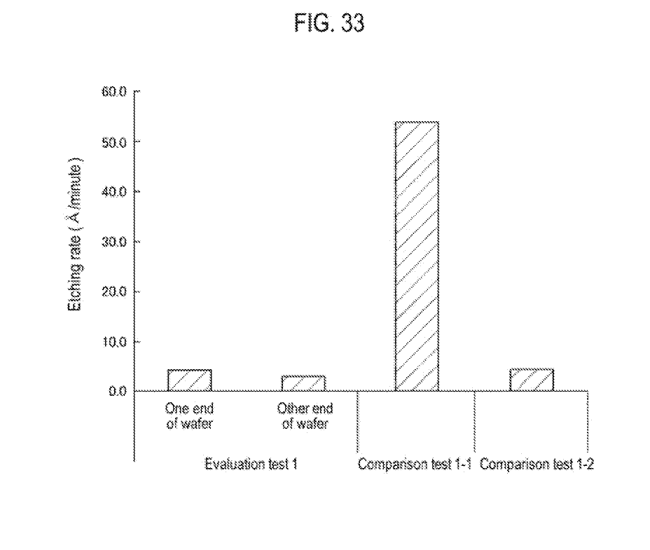

FIG. 33 is a graph illustrating the measured results of the etching rates of the evaluation test 1 and the comparison tests. In FIG. 33, a longitudinal axis indicates an etching rate (unit: Å/min). As illustrated in the graph, an etching rate on one side of the wafer W in the evaluation test 1 is 4.8 Å/min and an etching rate on the other side of the wafer W in the evaluation test is 3.4 Å/min, which are almost the same. Further, an etching rate in the comparison test 1-1 is 54.2 Å/min, and an etching rate in the comparison test 1-2 is 4.7 Å/min. In other words, the etching rates in the evaluation test 1 were suppressed to be lower than that in the comparison test 1-1 in which the processing was performed at the same room temperature, and are almost the same as the etching rate in the comparison test 1-2 in which the heating was performed using the heater in order to perform oxidation. In other words, it was found that in the evaluation test 1, the silicon oxide film having almost the same film quality as the silicon oxide film formed by heating during the film formation was formed. Accordingly, the results of the evaluation test revealed that the silicon oxide film having good film quality could be formed using the method in accordance with the embodiments of the present disclosure, although heating is not performed using a heater, as described in the embodiments.

Subsequently, an evaluation test 2 performed to examine a heat history of the silicon oxide film formed by performing the processes according to the embodiments is described below. In the evaluation test 2, phosphorus (P) was injected into a plurality of substrates made of silicon through ion implantation. The ion implantation was performed at 2 keV and 1E15 ions/cm². Further, using the film formation apparatus used in the evaluation test 1, a silicon oxide film was formed on the substrates into which phosphorous (P) was injected. In forming the silicon oxide film, the cycle was performed 100 times. Further, in Step S3 of each cycle, an ozone gas was supplied so that an ozone concentration within the processing space in the vacuum chamber became 77.7 Vol. %. Further, after the silicon oxide film was formed, the resistance value of the silicon oxide film was measured. Further, heating processing was performed on substrates that belong to the substrates into which phosphorous (P) was injected and on which the silicon oxide film was not formed at different temperatures for 5 minutes as references. After the heating process, the resistance values of the references were measured.

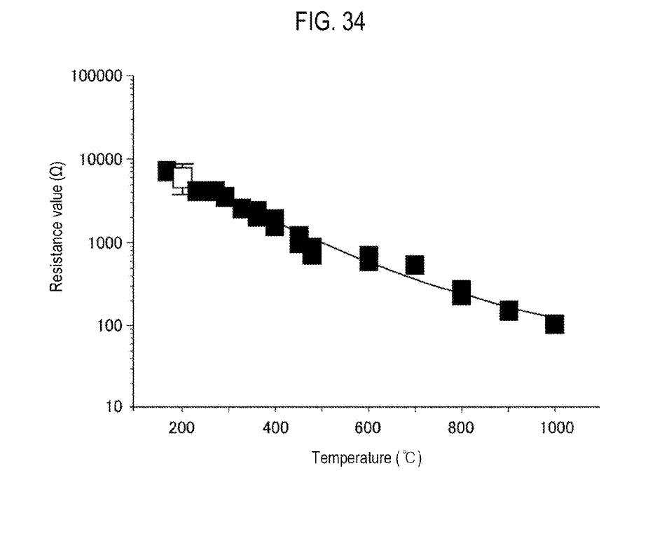

FIG. 34 is a graph illustrating the results of the evaluation test 2. Plots indicated by dark are the resistance values of the references, and a white plot is the resistance value of the silicon oxide film formed using the film formation apparatus 1. As illustrated in the graph, the resistance value of the silicon oxide film corresponds to the resistance values of the references heated at 200 degrees C. In other words, the execution of 100 cycles described in the embodiment corresponds to the application of heat to the substrate at 200 degrees C. for 5 minutes. In other words, it is supposed that, as described in the embodiments, aminosilane can be oxidized without heating the substrate using the heater as described above, because heat is applied to the substrate through the chain decomposition reaction as described above.

In accordance with the embodiments of the present disclosure, an ozone atmosphere capable of generating a forced decomposition reaction (chain decomposition reaction) within the processing space is formed, and the raw material adsorbed to the substrate is oxidized using the active species of oxygen generated by the decomposition reaction. Relatively great energy is applied to a surface of the substrate for a very short time through the decomposition reaction, whereby active species react with the raw material. Therefore, although the substrate is not heated using a heating mechanism, such as a heater, the oxidation may be sufficiently performed, thereby obtaining an oxide film having good properties. Further, when the decomposition reaction is generated, the processing space communicates with the buffer region to which an inert gas is supplied, thus suppressing an excessive rise of pressure within the processing space. As a result, the damage or deterioration of the substrate and the processing space formation member can be suppressed.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film formation apparatus configured to obtain a thin film by stacking a molecule layer of oxide on a surface of a substrate loaded onto a table under a vacuum atmosphere formed within a vacuum chamber, the film formation apparatus comprising:
a rotation mechanism configured to repeat alternately placing the substrate in a first region and a second region disposed in a circumference direction of the table over the table by rotating the table with respect to the first region and the second region;
a raw material gas supply unit configured to supply the first region with a raw material in a gaseous state as a raw material gas so that the raw material is adsorbed to the substrate;
a processing space formation member configured to move up and down with respect to the table in order to form a processing space near the substrate placed in the second region, the processing space being isolated from the first region;
an atmosphere gas supply unit configured to supply an atmosphere gas for forming an ozone atmosphere including an ozone of a concentration that is equal to or higher than a concentration at which a chain decomposition reaction is generated in the processing space;
an energy supply unit configured to forcibly decompose the ozone by supplying an energy to the ozone atmosphere so that active species of oxygen are generated and to obtain the oxide by oxidizing the raw material adsorbed to a surface of the substrate by the active species;
a buffer region configured to be connected to the processing space in order to reduce a rise of pressure in the processing space attributable to the decomposition of the ozone, the buffer region being supplied with an inert gas; and
a partition unit configured to partition the buffer region from the processing space when the atmosphere gas is supplied to the processing space and to have the buffer region communicate with the processing space when the decomposition of the ozone is generated.

2. The film formation apparatus of claim 1, wherein the partition unit has the buffer space communicate with the processing space before the energy supply unit supplies the energy after the atmosphere gas is supplied to the processing space.

3. The film formation apparatus of claim 1,
wherein the buffer region is installed in the processing space formation member,
wherein the partition unit is a lifting unit for moving the processing space formation member up and down, and
wherein a state in which the buffer region has been partitioned from the processing space and a state in which the processing space has communicated with the buffer region are switched depending on a height of the processing space formation member with respect to the table.

4. The film formation apparatus of claim 3,
wherein the processing space and the buffer region communicate with each other through a gap between the processing space formation member and the table,
wherein a protrusion configured to surround the processing space and the gap and isolate the processing space and the gap from an outside of the processing space formation member are formed on one of the processing space formation member and the table, and
wherein a groove engaged with the protrusion is formed on the other of the processing space formation member and the table.

5. The film formation apparatus of claim 1,
wherein the buffer region is connected to the processing space through a gas passage, and
wherein the partition unit includes a valve installed in the gas passage.

6. The film formation apparatus of claim 1,
wherein the buffer region further functions as an exhaust path for exhausting the processing space, and
wherein the partition unit includes a value installed in the exhaust path.

7. The film formation apparatus of claim 1, wherein the energy supply unit includes a reaction gas supply unit configured to supply the ozone atmosphere with a reaction gas for generating the forced decomposition through a chemical reaction between the reaction gas and the ozone.

8. The film formation apparatus of claim 7, wherein the reaction gas includes nitrogen monoxide.

9. A film formation method for obtaining a thin film by stacking a molecule layer of oxide on a surface of a substrate loaded onto a table under a vacuum atmosphere formed within a vacuum chamber, the film formation method comprising:
repeating to alternately placing the substrate in a first region and second region disposed in a circumference direction of the table over the table by rotating the table with respect to the first region and the second region;
supplying the first region with a raw material in a gaseous state as a raw material gas so that the raw material is adsorbed to the substrate;
moving a processing space formation member up and down with respect to the table in order to form a processing space near the substrate placed in the second region, the processing space being isolated from the first region;
supplying an atmosphere gas for forming an ozone atmosphere including an ozone of a concentration that is equal to or higher than a concentration at which a chain decomposition reaction is generated in the processing space;
forcibly decomposing the ozone by supplying an energy to the ozone atmosphere so that active species of oxygen are generated, and obtaining the oxide by oxidizing the raw material adsorbed to a surface of the substrate by the active species;
supplying an inert gas to a buffer region formed to reduce a rise of pressure in the processing space attributable to the decomposition of the ozone; and
partitioning the buffer region from the processing space when the atmosphere gas is supplied to the processing space, and having the buffer region communicate with the processing space when the decomposition of the ozone is generated.

10. The film formation method of claim 9, wherein having the buffer region communicate with the processing space is performed before supplying the energy to the ozone atmosphere after supplying the atmosphere gas.

11. The film formation method of claim 9, wherein supplying the energy is performed by supplying the ozone atmosphere with a reaction gas for generating the forced decomposition through a chemical reaction between the reaction gas and the ozone.

12. The film formation method of claim 11, wherein the reaction gas includes nitrogen monoxide.

13. A non-transitory computer-readable storage medium in which a computer program used in a film formation apparatus configured to obtain a thin film by stacking a molecule layer of oxide on a surface of a substrate under a vacuum atmosphere formed within a vacuum chamber has been stored, wherein the computer program includes steps organized so as to execute the film formation method of claim 9.
